(19) United States
(12) Patent Application Publication
(10) Pub. No.: US 2025/0023547 A1
(43) Pub. Date: Jan. 16, 2025

(54) BULK ACOUSTIC WAVE RESONATOR AND ELECTRONIC DEVICE

(71) Applicants: Beijing BOE Technology Development Co., Ltd., Beijing (CN); BOE TECHNOLOGY GROUP CO., LTD., Beijing (CN)

(72) Inventors: Xiyuan WANG, Beijing (CN); Feng QU, Beijing (CN); Biqi LI, Beijing (CN)

(21) Appl. No.: 18/279,046

(22) PCT Filed: Oct. 26, 2022
(86) PCT No.: PCT/CN2022/127591

§ 371 Date: Aug. 25, 2023

(51) Int. Cl. H03H 9/17; H03H 3/02; H03H 9/02

(52) U.S. Cl. CPC H03H 9/173; H03H 3/02; H03H 9/02102; H03H 9/175; H03H 2003/021; H03H 2003/025

(57) ABSTRACT

The present disclosure provides a bulk acoustic wave resonator and an electronic device, and belongs to the field of communication technology. The bulk acoustic wave resonator of the present disclosure includes: a base substrate, a first electrode, a piezoelectric layer, and a second electrode; the first electrode is on the base substrate, the second electrode is on a side of the first electrode away from the base substrate, the piezoelectric layer is between the first electrode and the second electrode; and orthographic projections of any two of the first electrode, the piezoelectric layer and the second electrode on the base substrate at least partially overlap with each other; wherein the bulk acoustic wave resonator further includes: a first heat conduction layer on a side of the first electrode close to the base substrate.

### TECHNICAL FIELD

The present disclosure relates to the field of communication technology, and in particular to a bulk acoustic wave resonator and an electronic device.

### BACKGROUND

In the field of mobile communications, the allocated total available frequency is in a narrow range, and there are many frequency bands used for the mobile communication, so that a spacing between adjacent frequency bands is narrow (about several MHz (megahertz) to tens of MHz), and a single frequency band has a narrow bandwidth (tens of MHz). Thus, a filter used in a mobile phone is required to have performance characteristics of a small in-band ripple, a large out-of-band rejection, and a good rectangularity. A conventional micro-strip filter has a large volume, an insufficient out-of-band rejection and a poor rectangularity and cannot meet the above requirement; a cavity filter has a large volume and cannot meet the above requirement; a dielectric filter has a large in-band insertion loss and a poor rectangularity and cannot meet the above requirement; an IPD (Integrated Passive Device) filter has a large in-band ripple and a poor rectangularity and cannot meet the above requirement.

A bulk acoustic wave resonator serves as an elementary unit of a structure of a bulk acoustic filter. The existing bulk acoustic wave resonator adopts a silicon wafer as a material of a base substrate with a sandwich structure, including a first electrode, a piezoelectric layer and a second electrode from bottom to top. The first electrode and the second electrode are metal electrodes, and the piezoelectric layer is made of a piezoelectric material.

An operating principle of the bulk acoustic wave resonator is: a radio frequency signal enters into the resonator from an electrode at one end of the resonator, then is converted into an acoustic wave signal of mechanical vibration at an interface of the piezoelectric material and the metal electrode through an inverse piezoelectric effect; the acoustic wave signal is formed as a resonant standing wave with a certain frequency in the sandwich structure including the first electrode, the piezoelectric layer and the second electrode; a frequency of the radio frequency signal is the same as a resonant frequency of the resonator; the acoustic wave signal is transmitted to the electrode at the other end of the resonator, and is converted into the radio frequency signal at the interface of the metal electrode and the piezoelectric material through a piezoelectric effect. The resonator has a fixed resonant frequency. When the frequency of the radio frequency signal is the same as the resonant frequency of the resonator, the conversion from the radio frequency signal to the acoustic wave signal to the radio frequency signal is high-efficiency; when the frequency of the radio frequency signal is not the same as the resonant frequency of the resonator, the conversion from the radio frequency signal to the acoustic wave signal to the radio frequency signal is low-efficiency, and most of the radio frequency signals cannot be transmitted through the resonator. That is, the resonator functions as a filter, which filters the radio frequency signals. In order to reduce the insertion loss during the filtering process, it is necessary to limit the acoustic wave signal inside the piezoelectric material as much as possible, to prevent the acoustic wave signal from diffusing out, so that acoustic wave reflectors are usually provided on upper and lower surfaces of the resonator.

### SUMMARY

The present disclosure aims to solve at least one technical problem in the prior art, and provides a bulk acoustic wave resonator and an electronic device.

An embodiment of the present disclosure provides a bulk acoustic wave resonator, including: a base substrate, a first electrode, a piezoelectric layer, and a second electrode; wherein the first electrode is on the base substrate, the second electrode is on a side of the first electrode away from the base substrate, the piezoelectric layer is between the first electrode and the second electrode; and orthographic projections of any two of the first electrode, the piezoelectric layer and the second electrode on the base substrate at least partially overlap with each other; wherein the bulk acoustic wave resonator further includes: a first heat conduction layer on a side of the first electrode close to the base substrate.

In some embodiments, the base substrate includes a first cavity extending through the base substrate in a thickness direction of the base substrate; the bulk acoustic wave resonator further includes a second heat conduction layer; the second heat conduction layer is on a side of the base substrate away from the first electrode, the second heat conduction layer covers the first cavity, and the second heat conduction layer is in contact with the first heat conduction layer through the first cavity.

In some embodiments, the base substrate further includes a plurality of heat conduction vias extending through the base substrate in the thickness direction of the base substrate; and a heat conduction electrode is in each heat conduction via, one end of the heat conduction electrode is in contact with the first heat conduction layer, and the other end of the heat conduction electrode is in contact with the second heat conduction layer.

In some embodiments, the bulk acoustic wave resonator further includes an isolation layer between the first electrode and the first heat conduction layer.

In some embodiments, the base substrate includes a first groove extending through a part of the base substrate in a thickness direction of the base substrate; an opening of the first groove faces to the first electrode; and an isolation layer is between the first heat conduction layer and the first electrode.

In some embodiments, the first thermal conduction layer includes a first heat conduction sub-layer and a second heat conduction sub-layer; the first heat conduction sub-layer is in the first groove and covers a side wall and a bottom wall of the first groove; the second heat conduction sub-layer is between the base substrate and the isolation layer, and the second heat conduction sub-layer and the first heat conduction sub-layer define an air gap in the first groove; and the second heat conduction sub-layer is in contact with the isolation layer.

In some embodiments, the base substrate includes a plurality of heat conduction vias extending through the base substrate in the thickness direction of the base substrate; the bulk acoustic wave resonator further includes a heat conduction electrode in each heat conduction via and a second heat conduction layer on a side of the base substrate away from the first heat conduction layer; and one end of the heat conduction electrode is in contact with the first heat conduction layer, and the other end of the heat conduction electrode is in contact with the second heat conduction layer.

In some embodiments, the bulk acoustic wave resonator further includes an isolation layer between the base substrate and the first electrode; a space is defined between the isolation layer and the base substrate.

In some embodiments, the first thermal conduction layer includes a first heat conduction sub-layer and a second heat conduction sub-layer; the first heat conduction sub-layer is on the base substrate; the second heat conduction sub-layer is on a surface of the isolation layer close to the base substrate; and the second heat conduction sub-layer and the first heat conduction sub-layer define an air gap. In some embodiments, the base substrate includes a plurality of heat conduction vias extending through the base substrate in a thickness direction of the base substrate; the bulk acoustic wave resonator further includes a heat conduction electrode in each heat conduction via and a second heat conduction layer on a side of the base substrate away from the first heat conduction layer; and one end of the heat conduction electrode is in contact with the first heat conduction layer, and the other end of the heat conduction electrode is in contact with the second heat conduction layer.

In some embodiments, the bulk acoustic wave resonator further includes at least one mirror structure between the base substrate and the first heat conduction layer; wherein the at least one mirror structure includes a first sub-structure layer and a second sub-structure layer which are sequentially arranged along a direction away from the base substrate, and an acoustic impedance of a material of the first sub-structure layer is greater than that of a material of the second sub-structure layer.

In some embodiments, the base substrate includes a plurality of heat conduction vias extending through the base substrate in a thickness direction of the base substrate; the bulk acoustic wave resonator further includes a heat conduction electrode in each heat conduction via and a second heat conduction layer on a side of the base substrate away from the first heat conduction layer; and one end of the heat conduction electrode is in contact with the first heat conduction layer, and the other end of the heat conduction electrode is in contact with the second heat conduction layer.

An embodiment of the present disclosure provides a method for manufacturing a bulk acoustic wave resonator, including: sequentially forming a first electrode, a piezoelectric layer and a second electrode on a base substrate, wherein orthographic projections of any two of the first electrode, the piezoelectric layer and the second electrode on the first base substrate at least partially overlap with each other; wherein the manufacturing method further includes: forming a first heat conduction layer on a side of the first electrode close to the base substrate.

In some embodiments, the method further includes: performing a treatment on the base substrate, to form a first cavity extending through the base substrate in a thickness direction of the base substrate; and forming a second heat conduction layer on a side of the base substrate away from the first electrode, wherein the second heat conduction layer covers the first cavity and is in contact with the first heat conduction layer through the first cavity.

In some embodiments, the method further includes: before the first heat conduction layer is formed, forming a plurality of heat conduction vias extending through the base substrate in the thickness direction of the base substrate; and forming a heat conduction electrode in each heat conduction via; and forming a second heat conduction layer on a side of the base substrate away from the first heat conduction layer; wherein one end of the heat conduction electrode is in contact with the first heat conduction layer, and the other end of the heat conduction electrode is in contact with the second heat conduction layer.

In some embodiments, the method further includes: forming an isolation layer between the step of forming the first electrode and the step of forming the first heat conduction layer.

In some embodiments, the method further includes: before the first heat conduction layer is formed, performing a treatment on the base substrate, to form a first groove; wherein an opening of the first groove faces to the first electrode; and forming an isolation layer.

In some embodiments, the first thermal conduction layer includes a first heat conduction sub-layer and a second heat conduction sub-layer; the forming the first thermal conduction layer includes forming the first heat conduction sub-layer in the first groove; the first heat conduction sub-layer covers a side wall and a bottom wall of the first groove; the second heat conduction sub-layer is formed between the base substrate and the isolation layer, and the second heat conduction sub-layer and the first heat conduction sub-layer define an air gap in the first groove; and the second heat conduction sub-layer is in contact with the isolation layer.

In some embodiments, the method further includes: before the first heat conduction layer is formed, forming a plurality of heat conduction vias extending through the base substrate in the thickness direction of the base substrate; and forming a heat conduction electrode in each heat conduction via; and forming a second heat conduction layer on a side of the base substrate away from the first heat conduction layer; wherein one end of the heat conduction electrode is in contact with the first heat conduction layer, and the other end of the heat conduction electrode is in contact with the second heat conduction layer.

In some embodiments, the method further includes: before the first electrode is formed, forming an isolation layer; wherein a space is defined between the isolation layer and the base substrate.

In some embodiments, the first thermal conduction layer includes a first heat conduction sub-layer and a second heat conduction sub-layer; forming the first thermal conduction layer includes forming the first heat conduction sub-layer on the base substrate; the second heat conduction sub-layer is formed on a surface of the isolation layer close to the base substrate; and the second heat conduction sub-layer and the first heat conduction sub-layer define an air gap.

In some embodiments, the method further includes: before the first heat conduction layer is formed, forming a plurality of heat conduction vias extending through the base substrate in the thickness direction of the base substrate; and forming a heat conduction electrode in each heat conduction via; and forming a second heat conduction layer on a side of the base substrate away from the first heat conduction layer; wherein one end of the heat conduction electrode is in contact with the first heat conduction layer, and the other end of the heat conduction electrode is in contact with the second heat conduction layer.

In some embodiments, the method further includes: forming at least one mirror structure between the step of forming the first heat conduction layer and the step of forming the first electrode; and forming each mirror structure includes sequentially forming a first sub-structure layer and a second sub-structure layer in a direction away from the first base substrate, and an acoustic impedance of a material of the first sub-structure layer is greater than that of a material of the second sub-structure layer.

In some embodiments, the method further includes: before the first heat conduction layer is formed, forming a plurality of heat conduction vias extending through the base substrate in the thickness direction of the base substrate; and forming a heat conduction electrode in each heat conduction via; and forming a second heat conduction layer on a side of the base substrate away from the first heat conduction layer; wherein one end of the heat conduction electrode is in contact with the first heat conduction layer, and the other end of the heat conduction electrode is in contact with the second heat conduction layer.

An embodiment of the present disclosure provides an electronic device, which includes the bulk acoustic wave resonator in any one of the above embodiments.

### BRIEF DESCRIPTION OF DRAWINGS

FIG. 1 is a schematic diagram of a structure of a back-etched bulk acoustic wave resonator.

FIG. 2 is a schematic diagram of a structure of a film bulk acoustic wave resonator.

FIG. 3 is another schematic diagram of a structure of a film bulk acoustic wave resonator.

FIG. 4 is a schematic diagram of a structure of a solid mounted bulk acoustic wave resonator.

FIG. 5 is a schematic diagram of a structure of a bulk acoustic wave resonator of a first example of an embodiment of the present disclosure.

FIG. 6 is a flow chart illustrating how to manufacture a bulk acoustic wave resonator shown in FIG. 5.

FIG. 7 is a schematic diagram of a structure of a bulk acoustic wave resonator of a second example of an embodiment of the present disclosure.

FIG. 8 is a flow chart illustrating how to manufacture a bulk acoustic wave resonator shown in FIG. 7.

FIG. 9 is a schematic diagram of a structure of a bulk acoustic wave resonator of a third example of an embodiment of the present disclosure.

FIG. 10 is a flow chart illustrating how to manufacture a bulk acoustic wave resonator shown in FIG. 9.

FIG. 11 is a schematic diagram of a structure of a bulk acoustic wave resonator of a fourth example of an embodiment of the present disclosure.

FIG. 12 is a flow chart illustrating how to manufacture a bulk acoustic wave resonator shown in FIG. 11.

FIG. 13 is a schematic diagram of a structure of a bulk acoustic wave resonator of a fifth example of an embodiment of the present disclosure.

FIG. 14 is a flow chart illustrating how to manufacture a bulk acoustic wave resonator shown in FIG. 13.

FIG. 15 is a schematic diagram of a structure of a bulk acoustic wave resonator of a sixth example of an embodiment of the present disclosure.

FIG. 16 is a flow chart illustrating how to manufacture a bulk acoustic wave resonator shown in FIG. 15.

FIG. 17 is a schematic diagram of a structure of a bulk acoustic wave resonator of a seventh example of an embodiment of the present disclosure.

FIG. 18 is a flow chart illustrating how to manufacture a bulk acoustic wave resonator shown in FIG. 17.

FIG. 19 is a schematic diagram of a structure of a bulk acoustic wave resonator of an eighth example of an embodiment of the present disclosure.

FIG. 20 is a flow chart illustrating how to manufacture a bulk acoustic wave resonator shown in FIG. 19.

FIG. 21 is a schematic diagram of a structure of a bulk acoustic wave resonator of a ninth example of an embodiment of the present disclosure.

FIG. 22 is a flow chart illustrating how to manufacture a bulk acoustic wave resonator shown in FIG. 21.

FIG. 23 is a schematic diagram of a structure of a bulk acoustic wave resonator of a tenth example of an embodiment of the present disclosure.

FIG. 24 is a flow chart illustrating how to manufacture a bulk acoustic wave resonator shown in FIG. 23.

FIG. 25 is a schematic diagram of a structure of a bulk acoustic wave resonator of an eleventh example of an embodiment of the present disclosure.

FIG. 26 is a flow chart illustrating how to manufacture a bulk acoustic wave resonator shown in FIG. 25.

### DETAIL DESCRIPTION OF EMBODIMENTS

In order to enable one of ordinary skill in the art to better understand the technical solutions of the present disclosure, the present disclosure will be described in further detail with reference to the accompanying drawings and the detailed description.

Unless defined otherwise, technical or scientific terms used herein shall have the ordinary meaning as understood by one of ordinary skill in the art to which the present disclosure belongs. The terms “first”, “second”, and the like used in the present disclosure are not intended to indicate any order, quantity, or importance, but rather are used for distinguishing one element from another. Further, the term “a”, “an”, “the”, or the like used herein does not denote a limitation of quantity, but rather denotes the presence of at least one element. The term “comprising”, “including”, or the like, means that the element or item preceding the term contains the element or item listed after the term and its equivalent, but does not exclude other elements or items. The term “connected”, “coupled”, or the like is not limited to a physical or mechanical connection, but may include an electrical connection, whether a direct or indirect connection. The terms “upper”, “lower”, “left”, “right”, and the like are used only for indicating relative positional relationships, and when the absolute position of an object being described is changed, the relative positional relationships may also be changed accordingly.

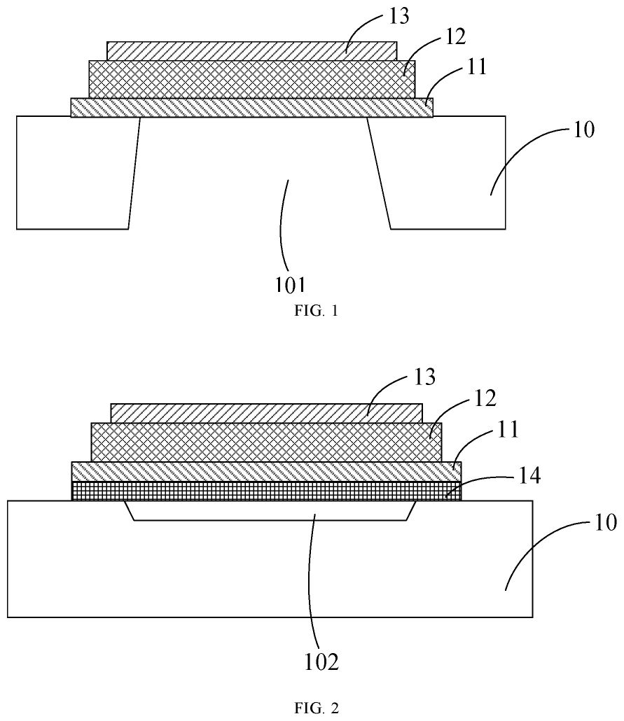

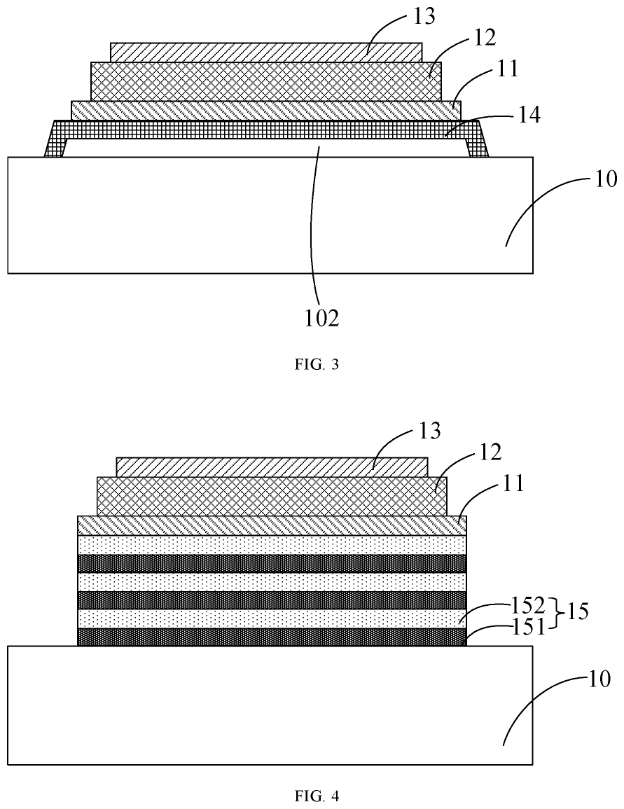

As shown in FIGS. 1 to 4, in order to reduce an insertion loss of a bulk acoustic wave resonator in a filtering process, it is necessary to limit an acoustic wave signal in a piezoelectric layer 12 between a first electrode and a second electrode 13 as much as possible, to prevent the acoustic wave signal from diffusing out, so that acoustic wave reflectors are usually provided on upper and lower surfaces of the resonator. A reflector is generally provided on the upper surface and is made of an air medium with a low acoustic impedance. Depending on the acoustic wave reflectors provided on the lower surface, the bulk acoustic wave resonators are divided into three major classes, that is, a back-etched bulk acoustic wave resonator as shown in FIG. 1; a film bulk acoustic wave resonator (abbreviated as FBAR) as shown in FIGS. 2 and 3; and a solid mounted resonator (abbreviated as SMR) as shown in FIG. 4. In the FBAR, a first groove 102 formed by etching under the first electrode on a base substrate 10 as an air gap, and then the first electrode is supported by an isolation layer 14, as shown in FIG. 2. Alternatively, the first groove 102 is formed as an air gap through the isolation layer 14, as shown in FIG. 3. In the SMR, high acoustic impedance layers 151 and low acoustic impedance layers 152 are alternately and repeatedly stacked under the first electrode as an acoustic mirror 15. In the back-etched bulk acoustic wave resonator, a first cavity 101 is formed under the first electrode in the base substrate 10 as an air layer by forming a cavity by deep etching back on the back of a silicon substrate.

The inventor has found that a tolerant power of an existing bulk acoustic wave resonator is generally less than or equal to 33 dBm. When the power is higher than 33 dBm, because the bulk acoustic wave resonator has certain insertion loss, a part of electromagnetic wave energy may be converted into heat, so that a temperature of a filter is increased sharply, which causes the drifting of a filter curve for the bulk acoustic wave resonator, and the reduction of the performance of the bulk acoustic wave resonator. When the temperature rises to a temperature close to a melting point of a material of the bulk acoustic wave resonator, the device fails, the filtering function is lost, or a link is directly disconnected.

In view of the foregoing problems, an embodiment of the present disclosure provides a bulk acoustic wave resonator, in which a first heat conduction layer is formed on a side of a first electrode of the bulk acoustic wave resonator close to a base substrate, so as to timely guide heat generated by a device to a material of the base substrate, thereby preventing the bulk acoustic wave resonator from failing due to a severe temperature rise.

A bulk acoustic wave resonator and a method for manufacturing the bulk acoustic wave resonator according to an embodiment of the present disclosure are described below by specific examples.

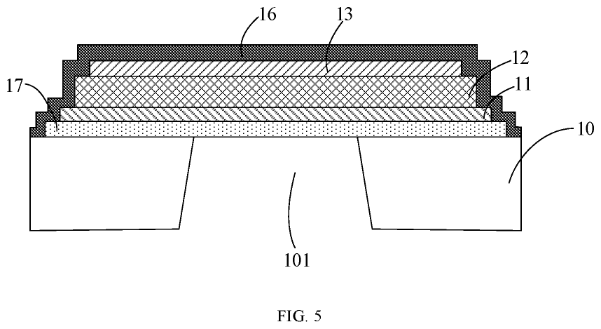

In a first example, FIG. 5 is a schematic diagram of a structure of a bulk acoustic wave resonator of a first example of an embodiment of the present disclosure. As shown in FIG. 5, the bulk acoustic wave resonator includes a base substrate 10, and a first heat conduction layer 17, a first electrode 11, a piezoelectric layer 13, and a second electrode 13 which are sequentially disposed on the base substrate 10. Orthographic projections of any two of the first electrode 11, the piezoelectric layer 13 and the second electrode 13 on the base substrate 10 at least partially overlap with each other. The base substrate 10 includes a first cavity 101 extending through the base substrate 10 in a thickness direction of the base substrate 10. The first electrode 11 is in contact with the first heat conduction layer 17 and is located within a region defined by the first heat conduction layer 17.

In some examples, an encapsulation layer 16 is further disposed on a side of the second electrode 13 away from the base substrate 10, to isolate the moisture and the oxygen and avoid the device damage.

In the bulk acoustic wave resonator in this example, the first heat conduction layer 17 is provided, and is in contact with the first electrode 11, so that the heat generated by the device can be effectively guided to the base substrate 10 in time, and the device is prevented from failing due to a sharp temperature rise.

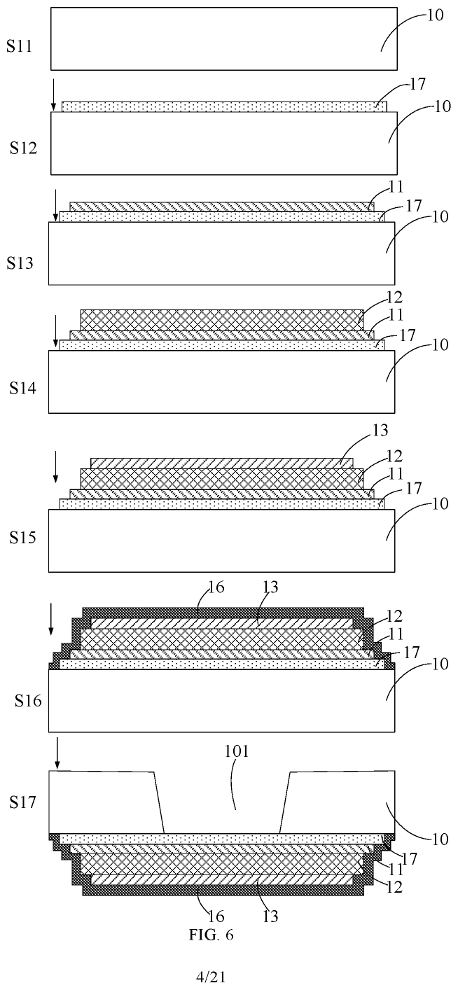

Next, a method of manufacturing the bulk acoustic wave resonator in the first example will be explained. As shown in FIG. 6, the manufacturing method specifically includes the following steps.

S11, providing a base substrate 10.

In some examples, the base substrate 10 may be a monocrystalline silicon substrate, or a glass, quartz, sapphire, SiC, GaAs, GaN, InP, BN, ZnO, or the like, and a thickness of the base substrate 10 is in a range from about 0.1 μm to about 10 mm.

The base substrate 10 is made of a monocrystalline silicon substrate, as an example, step S11 may specifically include: firstly, performing an ultrasonic cleaning on the monocrystalline silicon substrate with deionized water; then putting the monocrystalline silicon substrate into H₂SO₄:H₂O=3:1 mixed solution, heating to 250° C. and washing for 15 minutes; then putting the monocrystalline silicon substrate into deionized water for ultrasonic cleaning; then putting the monocrystalline silicon substrate into NH₄OH:H₂O=1:6, heating to 80° C. and washing for 15 minutes; taking out the monocrystalline silicon substrate and putting the monocrystalline silicon substrate into deionized water for washing; then putting the monocrystalline silicon substrate into HCl:H₂O₂:H₂O=1:1:5 mixed solution, heating to 85° C. and washing for 15 minutes; taking out the monocrystalline silicon substrate and putting the monocrystalline silicon substrate into dilute hydrofluoric acid of HF:H₂O=1:20 for rinsing for 10 seconds, to remove an oxide layer on a surface; and finally, putting the monocrystalline silicon substrate into deionized water for ultrasonic cleaning for 20 minutes, and drying the base substrate by using an air knife, to finish the cleaning process for the whole base substrate 10.

S12, forming a first heat conduction layer 17 on the base substrate 10.

In some examples, a material of the first heat conduction layer 17 is a metal material, such as the metal Cu which has a high thermal conductivity. The material of the first heat conduction layer 17 may alternatively be selected from metals such as Al, Mo, Co, Ag, Ti, Pt, Ru, W, Au, and alloys formed by any combination thereof, and a thickness of the first heat conduction layer 17 is in a range from about 10 nm to 50 μm.

When the first heat conduction layer 17 is made of a metal material, the step S12 may specifically include: depositing a first metal film on the base substrate 10 preferably by a direct current magnetron sputtering process (or a radio frequency magnetron sputtering process) or by a pulsed laser sputtering (PLD) process, a molecular beam epitaxy (MBE) process, a thermal evaporation process, an electron beam evaporation process, or the like; or by attaching a copper foil. In order to increase a thickness of the metal to facilitate the heat conduction, an electroplating thickening process may be performed. Then, a photolithography process is performed on the first metal film layer, including coating glue (or spraying glue), pre-baking, exposing, developing and post-baking. An etching process is then performed, to form a pattern including the first heat conduction layer 17, and the etching process is preferably a wet etching process, or a dry etching process. Finally, a photoresist removing process is performed, so that the first heat conduction layer 17 has been formed.

S13, forming a first electrode 11 on a side of the first heat conduction layer 17 away from the base substrate 10.

In some examples, a material of the first electrode 11 is a metal material, such as the metal Mo. The material of the first electrode 11 may alternatively be selected from metals such as Cu, Al, Co, Ag, Ti, Pt, Ru, W, Au, and alloys formed by any combination thereof. A thickness of the first electrode 11 is in a range from about 1 nm to 10 μm.

When the first electrode 11 is made of a metal material, the step S13 may include depositing a second metal film on a side of the first heat conduction layer 17 away from the base substrate 10 through preferably a direct current magnetron sputtering (or a radio frequency magnetron sputtering) or through a pulsed laser sputtering (PLD), a molecular beam epitaxy (MBE), a thermal evaporation, an electron beam evaporation, or the like; or by attaching a copper foil. Then, a photolithography process is performed on the second metal film, including coating glue (or spraying glue), pre-baking, exposing, developing and post-baking. An etching process is then performed, to form a pattern including the first electrode 11, and the etching process is preferably a wet etching process, or a dry etching process. Finally, a photoresist removing process is performed, so that the electrode 11 has been formed.

S14, forming a piezoelectric layer 13 on a side of the first electrode 11 away from the base substrate 10.

In some examples, a material of the piezoelectric layer 13 is a piezoelectric material, such as: AlN. Alternatively, the material of the piezoelectric layer 12 may be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, PVDF, etc. The piezoelectric layer 12 may be formed by one layer of the piezoelectric material, or may be formed by a stack of the above piezoelectric materials. A thickness of the piezoelectric layer 12 is in a range of 10 nm to 100 μm.

As an example, the piezoelectric layer 13 is an AlN single-layer structure, the step S14 may include forming a piezoelectric material layer on a side of the first electrode 11 away from the base substrate 10, and performing an orientation growth on the piezoelectric material layer preferably by radio frequency magnetron sputtering (or a direct current magnetron sputtering). A target material is selected as Al for the piezoelectric material of AlN. An AlN C-axis oriented piezoelectric material layer is formed by controlling an air pressure and a temperature of Ar and N₂ and a time and temperature of post-annealing in the deposition, and preferably the growth orientation is (001). The deposition process for the piezoelectric material layer may be selected from a pulsed laser sputtering (PLD), a molecular beam epitaxy (MBE), a metal organic chemical vapor deposition (MOCVD), a plasma enhanced chemical vapor deposition (PECVD), and the like. The piezoelectric layer 13 is subjected to a photolithography process including coating glue (or spraying glue), pre-baking, exposing, developing and post-baking. Then, the etching process is performed, to form a pattern of the piezoelectric layer 13. A preferred etching process may be a wet etching process or a dry etching process. Finally, a photoresist removing process is performed, so that the piezoelectric layer 13 has been formed.

S15, forming a second electrode 13 on a side of the piezoelectric layer 13 away from the first electrode 11.

In some examples, a material of the second electrode 13 may be selected from metal materials, such as Cu, Al, Mo, Co, Ag, Ti, Pt, Ru, W, Au, and alloys formed by any combination thereof. A thickness of the second electrode 13 is in a range from about 1 nm to 10 μm.

When the second electrode 13 is made of a metal material, step S15 may specifically include: depositing a third metal film on a side of the piezoelectric layer 13 away from the first electrode 11 through preferably a direct current magnetron sputtering (or a radio frequency magnetron sputtering) or through a pulsed laser sputtering (PLD), a molecular beam epitaxy (MBE), a thermal evaporation, an electron beam evaporation, or the like. Then, a photolithography process is performed on the third metal film, including coating glue (or spraying glue), pre-baking, exposing, developing and post-baking. An etching process is then performed, to form a pattern including the second electrode 13. The etching process is preferably a wet etching process, or a dry etching process. Finally, a photoresist removing process is performed, so that the second electrode 13 has been formed.

S16, forming an encapsulation layer 16 on a side of the second electrode 13 away from the base substrate 10.

In some examples, a material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

As an example, the material of the encapsulation layer 16 is the organic compound material, the step S16 may specifically include performing liquid coating of the organic material, such as spin coating, spraying, ink-jet printing, or transferring or the like, and then performing a heat curing process to form a pattern of the encapsulation layer 16.

S17, turning over the base substrate 10 with the above structure, and forming a first cavity 101 extending through the base substrate in a thickness direction of the base substrate by etching.

In some examples, step S17 may include turning over the base substrate 10 with the above structure, forming a mask pattern on the back of the base substrate 10, and performing a photolithography process including coating glue (or spraying glue), pre-baking, exposing, developing and post-baking. Then, HF acid wet etching is performed, to form the first cavity 101; and finally, a photoresist removing process is performed.

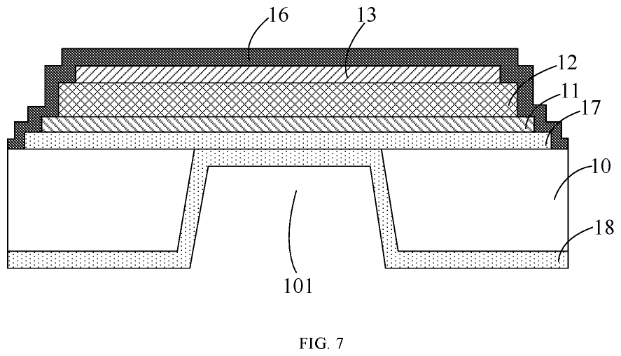

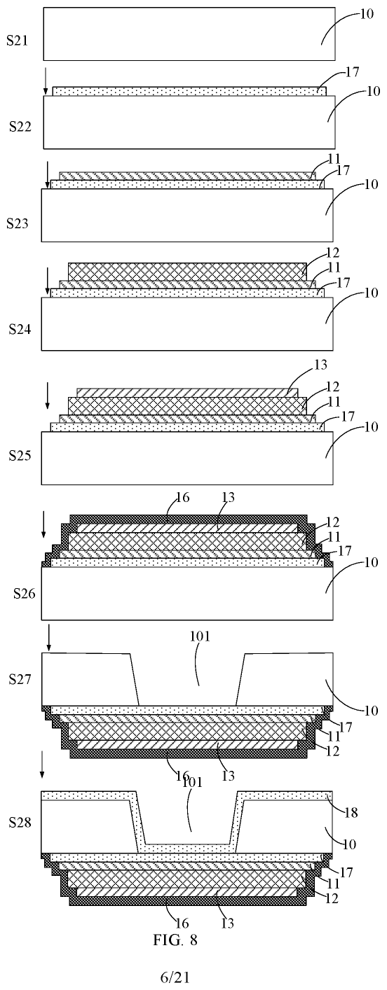

In a second example, FIG. 7 is a schematic diagram of a structure of a bulk acoustic wave resonator of a second example of an embodiment of the present disclosure. As shown in FIG. 7, the bulk acoustic wave resonator includes a base substrate 10, a first heat conduction layer 17, a first electrode 11, a piezoelectric layer 13, and a second electrode 13, which are sequentially disposed on the base substrate 10, and a second heat conduction layer 18 disposed on a side of the base substrate 10 away from the first electrode 11. Orthographic projections of any two of the first electrode 11, the piezoelectric layer 13 and the second electrode 13 on the base substrate 10 at least partially overlap with each other. The base substrate 10 includes a first cavity 101 extending through the base substrate 10 in a thickness direction of the base substrate 10. The first electrode 11 is in contact with the first heat conduction layer 17 and is located within a region defined by the first heat conduction layer 17. The second heat conduction layer 18 covers the first cavity 101 and is in contact with the first heat conduction layer 17 through the first cavity 101.

In some examples, an encapsulation layer 16 is further disposed on a side of the second electrode 13 away from the base substrate 10, to isolate the moisture and the oxygen and avoid the device damage.

In the bulk acoustic wave resonator in this example the first heat conduction layer 17 and the second heat conduction layer 18 are provided, the first heat conduction layer 17 is in contact with the first electrode 11, and the second heat conduction layer 18 is in contact with the first heat conduction layer 17. The heat generated by the device can be effectively guided by the first heat conduction layer 17 to the base substrate 10 in time, and then the heat is guided by the second heat conduction layer 18 to a board to be bonded later, so that the device is prevented from failing due to a sharp temperature rise.

Next, a method for manufacturing a bulk acoustic wave resonator in the second example will be described. As shown in FIG. 8, the manufacturing method specifically includes the following steps.

S21, providing a base substrate 10.

In some examples, the base substrate 10 may be a monocrystalline silicon substrate, or a glass, quartz, sapphire, SiC, GaAs, GaN, InP, BN, ZnO, or the like, and a thickness of the base substrate 10 is in a range from about 0.1 μm to about 10 mm.

The base substrate 10 is made of a monocrystalline silicon substrate, as an example, step S21 may specifically include: firstly, performing an ultrasonic cleaning on the monocrystalline silicon substrate with deionized water; then putting the monocrystalline silicon substrate into H₂SO₄:H₂O=3:1 mixed solution, heating to 250° C. and washing for 15 minutes; then putting the monocrystalline silicon substrate into deionized water for ultrasonic cleaning; then putting the monocrystalline silicon substrate into NH₄OH:H₂O=1:6, heating to 80° C. and washing for 15 minutes; taking out the monocrystalline silicon substrate and putting the monocrystalline silicon substrate into deionized water for washing; then putting the monocrystalline silicon substrate into HCl:H₂O₂:H₂O=1:1:5 mixed solution, heating to 85° C. and washing for 15 minutes; taking out the monocrystalline silicon substrate and putting the monocrystalline silicon substrate into dilute hydrofluoric acid of HF:H₂O=1:20 for rinsing for 10 seconds, to remove an oxide layer on a surface; and finally, putting the monocrystalline silicon substrate into deionized water for ultrasonic cleaning for 20 minutes, and drying the base substrate by using an air knife, to finish the cleaning process for the whole base substrate 10.

S22, forming a first heat conduction layer 17 on the base substrate 10.

In some examples, a material of the first heat conduction layer 17 is a metal material, such as the metal Cu which has a high thermal conductivity. The material of the first heat conduction layer 17 may alternatively be selected from metals such as Al, Mo, Co, Ag, Ti, Pt, Ru, W, Au, and alloys formed by any combination thereof, and a thickness of the first heat conduction layer 17 is in a range from about 10 nm to 50 μm.

When the first heat conduction layer 17 is made of a metal material, the step S22 may specifically include: depositing a first metal film on the base substrate 10 through preferably a direct current magnetron sputtering (or a radio frequency magnetron sputtering) or through a pulsed laser sputtering (PLD), a molecular beam epitaxy (MBE), a thermal evaporation, an electron beam evaporation, or the like; or by attaching a copper foil. In order to increase a thickness of the metal to facilitate the heat conduction, an electroplating thickening process may be performed. Then, a photolithography process is performed on the first metal film layer, including coating glue (or spraying glue), pre-baking, exposing, developing and post-baking. An etching process is then performed, to form a pattern including the first heat conduction layer 17, and the etching process is preferably a wet etching process, or a dry etching process. Finally, a photoresist removing process is performed, so that the first heat conduction layer 17 has been formed.

S23, forming a first electrode 11 on a side of the first heat conduction layer 17 away from the base substrate 10.

In some examples, a material of the first electrode 11 is a metal material, such as the metal Mo. The material of the first electrode 11 may alternatively be selected from metals such as Cu, Al, Co, Ag, Ti, Pt. Ru, W, Au, and alloys formed by any combination thereof. A thickness of the first electrode 11 is in a range from about 1 nm to 10 μm.

When the first electrode 11 is made of a metal material, the step S23 may include depositing a second metal film on a side of the first heat conduction layer 17 away from the base substrate 10 through preferably a direct current magnetron sputtering (or a radio frequency magnetron sputtering) or through a pulsed laser sputtering (PLD), a molecular beam epitaxy (MBE), a thermal evaporation, an electron beam evaporation, or the like; or by attaching a copper foil. Then, a photolithography process is performed on the second metal film, including coating glue (or spraying glue), pre-baking, exposing, developing and post-baking. An etching process is then performed, to form a pattern including the first electrode 11, the etching process is preferably a wet etching process, or a dry etching process. Finally, a photoresist removing process is performed, so that the electrode 11 has been formed.

S24, forming a piezoelectric layer 13 on a side of the first electrode 11 away from the base substrate 10.

In some examples, a material of the piezoelectric layer 13 is a piezoelectric material, such as: AlN. Alternatively, the material of the piezoelectric layer 12 may be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, PVDF, etc. The piezoelectric layer 12 may be formed by one layer of the piezoelectric material, or may be formed by a stack of the above piezoelectric materials. A thickness of the piezoelectric layer 12 is in a range of 10 nm to 100 μm.

As an example, the piezoelectric layer 13 is an AlN single-layer structure, the step S24 may include forming a piezoelectric material layer on a side of the first electrode 11 away from the base substrate 10, and performing an orientation growth on the piezoelectric material layer preferably by radio frequency magnetron sputtering (or a direct current magnetron sputtering). A target material is selected as Al for the piezoelectric material of AlN. An AlN C-axis oriented piezoelectric material layer is formed by controlling an air pressure and a temperature of Ar and N₂ and a time and temperature of post-annealing in the deposition, and preferably the growth orientation is (001). The deposition process for the piezoelectric material layer may be selected from a pulsed laser sputtering (PLD), a molecular beam epitaxy (MBE), a metal organic chemical vapor deposition (MOCVD), a plasma enhanced chemical vapor deposition (PECVD), and the like. The piezoelectric layer 13 is subjected to a photolithography process including coating glue (or spraying glue), pre-baking, exposing, developing and post-baking. Then, the etching process is performed, to form a pattern of the piezoelectric layer 13. A preferred etching process may be a wet etching process or a dry etching process. Finally, a photoresist removing process is performed, so that the piezoelectric layer 13 has been formed.

S25, forming a second electrode 13 on a side of the piezoelectric layer 13 away from the first electrode 11.

In some examples, a material of the second electrode 13 may be selected from metal materials, such as Cu, Al, Mo, Co, Ag, Ti, Pt, Ru, W, Au, and alloys formed by any combination thereof. A thickness of the second electrode 13 is in a range from about 1 nm to 10 μm.

When the second electrode 13 is made of a metal material, step S25 may specifically include: depositing a third metal film on a side of the piezoelectric layer 13 away from the first electrode 11 through preferably a direct current magnetron sputtering (or a radio frequency magnetron sputtering) or through a pulsed laser sputtering (PLD), a molecular beam epitaxy (MBE), a thermal evaporation, an electron beam evaporation, or the like. Then, a photolithography process is performed on the third metal film, including coating glue (or spraying glue), pre-baking, exposing, developing and post-baking. An etching process is then performed, to form a pattern including the second electrode 13. The etching process is preferably a wet etching process, or a dry etching process. Finally, a photoresist removing process is performed, so that the second electrode 13 has been formed.

S26, forming an encapsulation layer 16 on a side of the second electrode 13 away from the base substrate 10.

In some examples, a material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

As an example, the material of the encapsulation layer 16 is the organic compound material, the step S26 may specifically include performing liquid coating of the organic material, such as spin coating, spraying, ink-jet printing, or transferring or the like, and then performing a heat curing process to form a pattern of the encapsulation layer 16.

S27, turning over the base substrate 10 with the above structure, and forming a first cavity 101 extending through the base substrate in a thickness direction of the base substrate by etching.

In some examples, step S27 may include turning over the base substrate 10 with the above structure, forming a mask pattern on the back of the base substrate 10, and performing a photolithography process including coating glue (or spraying glue), pre-baking, exposing, developing and post-baking. Then, HF acid wet etching is performed, to form the first cavity 101; and finally, a photoresist removing process is performed.

S28, forming a second heat conduction layer 18 on a side of the base substrate 10 away from the first electrode 11.

In some examples, the materials of the second heat conduction layer 18 and the first heat conduction layer 17 may be the same. The step S28 may specifically include: depositing a fourth metal film on the base substrate 10 through preferably a direct current magnetron sputtering (or a radio frequency magnetron sputtering) or through a pulsed laser sputtering (PLD), a molecular beam epitaxy (MBE), a thermal evaporation, an electron beam evaporation, or the like; or by attaching a copper foil. In order to increase a thickness of the metal to facilitate the heat conduction, an electroplating thickening process may be performed. Then, a photolithography process is performed on the second metal film layer, including coating glue (or spraying glue), pre-baking, exposing, developing and post-baking. An etching process is then performed, to form a pattern including the second heat conduction layer, and the etching process is preferably a wet etching process, or a dry etching process. Finally, a photoresist removing process is performed, so that the second heat conduction layer 18 has been formed.

It should be noted that a part of the second heat conduction layer 18 is a metal pad area bonding to a circuit board, to transfer heat generated by the device to the circuit board in time.

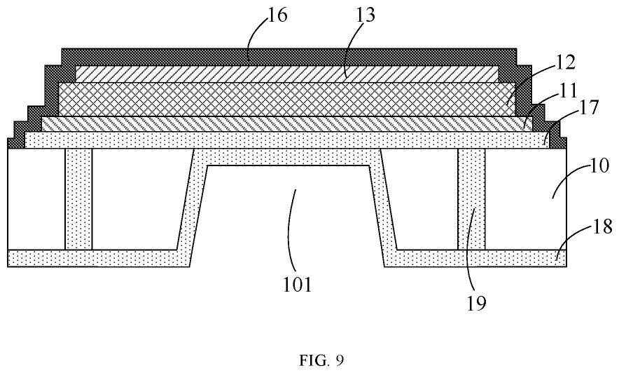

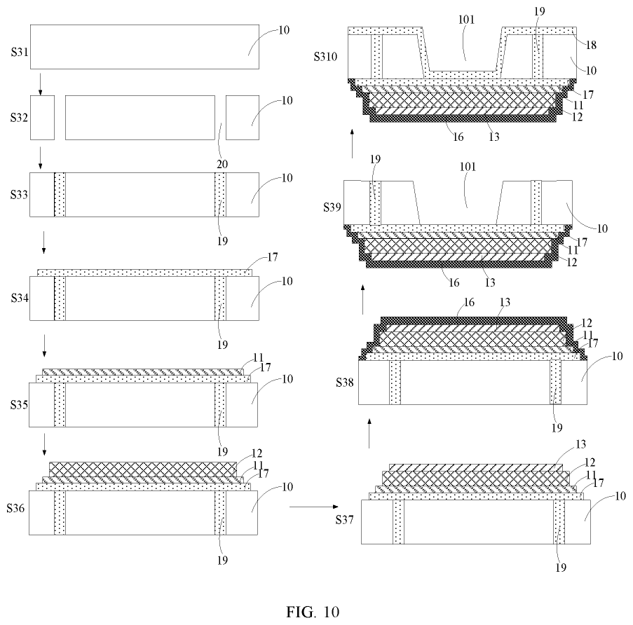

In a third example: FIG. 9 is a schematic diagram of a structure of a bulk acoustic wave resonator of a third example of an embodiment of the present disclosure. As shown in FIG. 9, the bulk acoustic wave resonator includes a base substrate 10, a first heat conduction layer 17, a first electrode 11, a piezoelectric layer 13, and a second electrode 13, which are sequentially disposed on the base substrate 10, and a second heat conduction layer 18 disposed on a side of the base substrate 10 away from the first electrode 11. Orthographic projections of any two of the first electrode 11, the piezoelectric layer 13 and the second electrode 13 on the base substrate 10 at least partially overlap with each other. The base substrate 10 includes a first cavity 101 extending through the base substrate 10 in a thickness direction of the base substrate 10, and a plurality of heat conduction vias 20. The first electrode 11 is in contact with the first heat conduction layer 17 and is located within a region defined by the first heat conduction layer 17. The second heat conduction layer 18 covers the first cavity 101 and is in contact with the first heat conduction layer 17 through the first cavity 101. A heat conduction electrode 19 is arranged in each of the heat conduction vias 20, one end of the heat conduction electrode 19 is in contact with the first heat conduction layer 17, and the other end of the heat conduction electrode 19 is in contact with the second heat conduction layer 18.

In some examples, an encapsulation layer 16 is further disposed on a side of the second electrode 13 away from the base substrate 10, to isolate the moisture and the oxygen and avoid the device damage.

In the bulk acoustic wave resonator in this example the first heat conduction layer 17 and the second heat conduction layer 18 are provided, the first heat conduction layer 17 is in contact with the first electrode 11, and the second heat conduction layer 18 is in contact with the first heat conduction layer 17. The heat generated by the device can be timely guided by the heat conduction electrode 19 through the first heat conduction layer 17 to the second heat conduction layer 18, and then the heat is guided by the second heat conduction layer 18 to a board to be bonded later, so that the device is prevented from failing due to a sharp temperature rise. The heat is guided out through the heat conduction electrode 19, so that the defect can be overcome that the base substrate 10 is low in heat conductivity and poor in heat dissipation effect. oxygen and avoid the device damage.

Next, a method for manufacturing the bulk acoustic wave resonator in the third example will be explained. As shown in FIG. 10, the manufacturing method specifically includes the following steps.

S31, providing a base substrate 10.

In some examples, the base substrate 10 may be a monocrystalline silicon substrate, or a glass, quartz, sapphire, SiC, GaAs, GaN, InP, BN, ZnO, or the like, and a thickness of the base substrate 10 is in a range from about 0.1 μm to about 10 mm.

The base substrate 10 is made of a monocrystalline silicon substrate, as an example, step S31 may specifically include: firstly, performing an ultrasonic cleaning on the monocrystalline silicon substrate with deionized water; then putting the monocrystalline silicon substrate into H₂SO₄:H₂O=3:1 mixed solution, heating to 250° C. and washing for 15 minutes; then putting the monocrystalline silicon substrate into deionized water for ultrasonic cleaning; then putting the monocrystalline silicon substrate into NH₄OH:H₂O=1:6, heating to 80° C. and washing for 15 minutes; taking out the monocrystalline silicon substrate and putting the monocrystalline silicon substrate into deionized water for washing; then putting the monocrystalline silicon substrate into HCl:H₂O₂:H₂O=1:1:5 mixed solution, heating to 85° C. and washing for 15 minutes; taking out the monocrystalline silicon substrate and putting the monocrystalline silicon substrate into dilute hydrofluoric acid of HF:H₂O=1:20 for rinsing for 10 seconds, to remove an oxide layer on a surface; and finally, putting the monocrystalline silicon substrate into deionized water for ultrasonic cleaning for 20 minutes, and drying the base substrate by using an air knife, to finish the cleaning process for the whole base substrate 10.

S32, forming a plurality of heat conduction vias 20 extending through the base substrate 10 in a thickness direction of the base substrate 10 in the base substrate 10.

In some examples, step S32 may include forming the plurality of heat conduction vias 20 extending through the base substrate 10 in the thickness direction of the base substrate 10 in the base substrate 10 by using a sand blasting method, a photosensitive glass method, a focus discharging method, a plasma etching method, a laser ablation method, an electrochemical method, a laser induced etching method, or the like.

S33, forming a heat conduction electrode 19 in each heat conduction via 20.

In some examples, a material of the heat conduction electrode 19 may be the same as that of the first heat conduction layer 17. Step S33 may include forming a seed layer on a wall of the formed heat conduction via 20 through a magnetron sputtering, a thermal evaporation, an electron beam evaporation, and the spraying of a chemical plating medium; then, performing a metal hole filling and thickening processes, so that the metal is filled in the via. Optional methods of the metal hole filling and thickening process include electroplating, chemical plating, metal paste extrusion and thermocuring sintering or infrared laser irradiation sintering. Finally, the substrate is pressed against a rough polishing pad by using a polishing head; the planarization of the surface of the substrate is realized by virtue of coupling effects such as polishing solution corrosion, particle friction, polishing pad friction or the like for a certain time; and a material overflowing from a surface of the heat conduction via 20 is subjected to a surface polish, so that a height of the material overflowing from a surface of the heat conduction via 20 is equal to a height of the surface of the base substrate 10, and thus, the heat conduction electrode 19 has been formed.

S34, forming a first heat conduction layer 17 on the base substrate 10.

In some examples, a material of the first heat conduction layer 17 is a metal material, such as the metal Cu which has a high thermal conductivity. The material of the first heat conduction layer 17 may alternatively be selected from metals such as Al, Mo, Co, Ag, Ti, Pt, Ru, W, Au, and alloys formed by any combination thereof, and a thickness of the first heat conduction layer 17 is in a range from about 10 nm to 50 μm.

When the first heat conduction layer 17 is made of a metal material, the step S34 may specifically include: depositing a first metal film on the base substrate 10 through preferably a direct current magnetron sputtering (or a radio frequency magnetron sputtering) or through a pulsed laser sputtering (PLD), a molecular beam epitaxy (MBE), a thermal evaporation, an electron beam evaporation, or the like; or by attaching a copper foil. In order to increase a thickness of the metal to facilitate the heat conduction, an electroplating thickening process may be performed. Then, a photolithography process is performed on the first metal film layer, including coating glue (or spraying glue), pre-baking, exposing, developing and post-baking. An etching process is then performed, to form a pattern including the first heat conduction layer 17, and the etching process is preferably a wet etching process, or a dry etching process. Finally, a photoresist removing process is performed, so that the first heat conduction layer 17 has been formed.

S35, forming a first electrode 11 on a side of the first heat conduction layer 17 away from the base substrate 10.

In some examples, a material of the first electrode 11 is a metal material, such as the metal Mo. The material of the first electrode 11 may alternatively be selected from metals such as Cu, Al, Co, Ag, Ti, Pt, Ru, W, Au, and alloys formed by any combination thereof. A thickness of the first electrode 11 is in a range from about 1 nm to 10 μm. When the first electrode 11 is made of a metal material, the step S35 may include depositing a second metal film on a side of the first heat conduction layer 17 away from the base substrate 10 through preferably a direct current magnetron sputtering (or a radio frequency magnetron sputtering) or through a pulsed laser sputtering (PLD), a molecular beam epitaxy (MBE), a thermal evaporation, an electron beam evaporation, or the like; or by attaching a copper foil. Then, a photolithography process is performed on the second metal film, including coating glue (or spraying glue), pre-baking, exposing, developing and post-baking. An etching process is then performed, to form a pattern including the first electrode 11, and the etching process is preferably a wet etching process, or a dry etching process. Finally, a photoresist removing process is performed, so that the electrode 11 has been formed.

S36, forming a piezoelectric layer 13 on a side of the first electrode 11 away from the base substrate 10.

In some examples, a material of the piezoelectric layer 13 is a piezoelectric material, such as: AlN. Alternatively, the material of the piezoelectric layer 12 may be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, PVDF, etc. The piezoelectric layer 12 may be formed by one layer of the piezoelectric material, or may be formed by a stack of the above piezoelectric materials. A thickness of the piezoelectric layer 12 is in a range of 10 nm to 100 μm.

As an example, the piezoelectric layer 13 is an AlN single-layer structure, the step S36 may include forming a piezoelectric material layer on a side of the first electrode 11 away from the base substrate 10, and performing an orientation growth on the piezoelectric material layer preferably by radio frequency magnetron sputtering (or a direct current magnetron sputtering). A target material is selected as Al for the piezoelectric material of AlN. An AlN C-axis oriented piezoelectric material layer is formed by controlling an air pressure and a temperature of Ar and N₂ and a time and temperature of post-annealing in the deposition, and preferably the growth orientation is (001). The deposition process for the piezoelectric material layer may be selected from a pulsed laser sputtering (PLD), a molecular beam epitaxy (MBE), a metal organic chemical vapor deposition (MOCVD), a plasma enhanced chemical vapor deposition (PECVD), and the like. The piezoelectric layer 13 is subjected to a photolithography process including coating glue (or spraying glue), pre-baking, exposing, developing and post-baking. Then, the etching process is performed, to form a pattern of the piezoelectric layer 13. A preferred etching process may be a wet etching process or a dry etching process. Finally, a photoresist removing process is performed, so that the piezoelectric layer 13 has been formed.

S37, forming a second electrode 13 on a side of the piezoelectric layer 13 away from the first electrode 11.

In some examples, a material of the second electrode 13 may be selected from metal materials, such as Cu, Al, Mo, Co, Ag, Ti, Pt, Ru, W, Au, and alloys formed by any combination thereof. A thickness of the second electrode 13 is in a range from about 1 nm to 10 μm.

When the second electrode 13 is made of a metal material, step S37 may specifically include: depositing a third metal film on a side of the piezoelectric layer 13 away from the first electrode 11 through preferably a direct current magnetron sputtering (or a radio frequency magnetron sputtering) or through a pulsed laser sputtering (PLD), a molecular beam epitaxy (MBE), a thermal evaporation, an electron beam evaporation, or the like. Then, a photolithography process is performed on the third metal film, including coating glue (or spraying glue), pre-baking, exposing, developing and post-baking. An etching process is then performed, to form a pattern including the second electrode 13. The etching process is preferably a wet etching process, or a dry etching process. Finally, a photoresist removing process is performed, so that the second electrode 13 has been formed.

S38, forming an encapsulation layer 16 on a side of the second electrode 13 away from the base substrate 10.

In some examples, a material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

As an example, the material of the encapsulation layer 16 is the organic compound material, the step S38 may specifically include performing liquid coating of the organic material, such as spin coating, spraying, ink-jet printing, or transferring or the like, and then performing a heat curing process to form a pattern of the encapsulation layer 16.

S39, turning over the base substrate 10 with the above structure, and forming a first cavity 101 extending through the base substrate in a thickness direction of the base substrate by etching.

In some examples, step S39 may include turning over the base substrate 10 with the above structure, forming a mask pattern on the back of the base substrate 10, and performing a photolithography process including coating glue (or spraying glue), pre-baking, exposing, developing and post-baking. Then, HF acid wet etching is performed, to form the first cavity 101; and finally, a photoresist removing process is performed.

S310, forming a second heat conduction layer 18 on a side of the base substrate 10 away from the first electrode 11.

In some examples, the materials of the second heat conduction layer 18 and the first heat conduction layer 17 may be the same. The step S310 may specifically include: depositing a fourth metal film on the base substrate 10 through preferably a direct current magnetron sputtering (or a radio frequency magnetron sputtering) or through a pulsed laser sputtering (PLD), a molecular beam epitaxy (MBE), a thermal evaporation, an electron beam evaporation, or the like; or by attaching a copper foil. In order to increase a thickness of the metal to facilitate the heat conduction, an electroplating thickening process may be performed. Then, a photolithography process is performed on the fourth metal film layer, including coating glue (or spraying glue), pre-baking, exposing, developing and post-baking. An etching process is then performed, to form a pattern including the second heat conduction layer, and the etching process is preferably a wet etching process, or a dry etching process. Finally, a photoresist removing process is performed, so that the second heat conduction layer 18 has been formed.

It should be noted that a part of the second heat conduction layer 18 is a metal pad area bonded to the circuit board, to transfer heat generated by the device to a circuit board in time.

In a fourth example: FIG. 11 is a schematic diagram of a structure of a bulk acoustic wave resonator of a fourth example of an embodiment of the present disclosure. As shown in FIG. 11, the structure of the bulk acoustic wave resonator in this example is substantially the same as that in the second example except that an isolation layer 21 is provided between the first electrode 11 and the first heat conduction layer 17. By providing the isolation layer 21, the leakage of electromagnetic wave signals can be effectively avoided, and the insertion loss is reduced.

In some examples, a material of the isolation layer 21 is preferably Si₃N₄, and alternatively SiO₂, Al₂O₃, etc., and a laminate formed by any combination thereof. A thickness of the isolation layer 21 is in a range from about 1 nm to 100 μm.

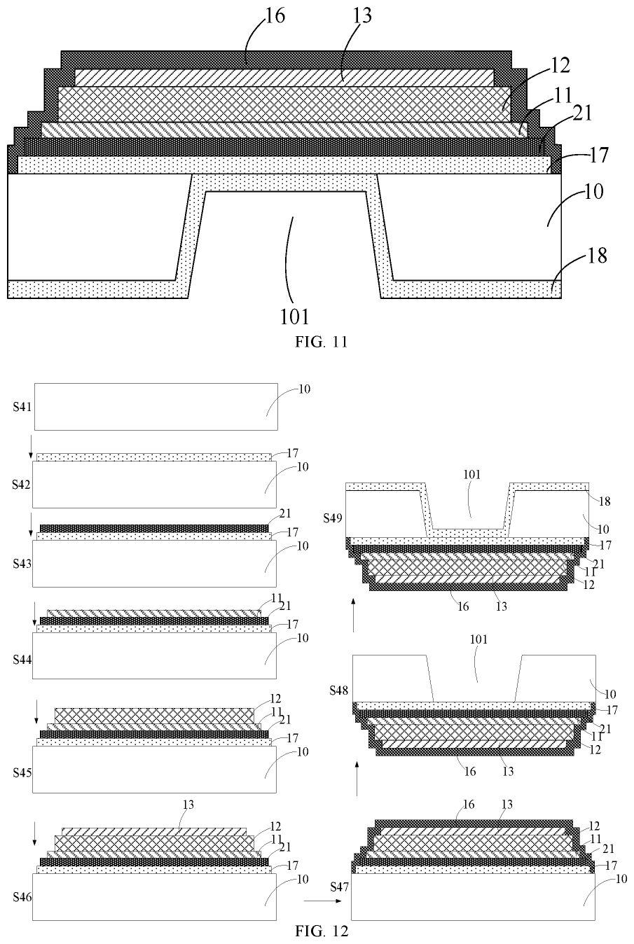

As shown in FIG. 12, a method for manufacturing the bulk acoustic wave resonator in the fourth example includes steps S41 to S49, wherein the steps S41 to S42 are respectively the same as the steps S21 to S22, and the steps S44 to S49 are respectively the same as the steps S23 to S28. Therefore, only step S43 will be described below.

Step S43 may include forming a film of the isolation layer 21 on a side of the base substrate 10 away from the first heat conduction layer 17, and depositing an electrical insulating material through a radio frequency magnetron sputtering, a pulsed laser sputtering (PLD), an atomic layer deposition (ALD), or a plasma enhanced chemical vapor deposition (PECVD). The isolation layer 21 is subjected to a photolithography process to form a pattern including the isolation layer 21, and the photolithography process includes coating glue (or spraying glue), pre-baking, exposing, developing and post-baking. An etching process is finally performed, and is preferably a wet etching process, or a dry etching process.

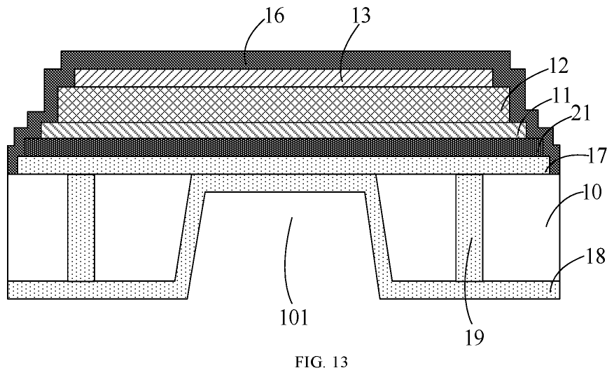

In a fifth example: FIG. 13 is a schematic diagram of a structure of a bulk acoustic wave resonator of a fifth example of an embodiment of the present disclosure. As shown in FIG. 13, the structure of the bulk acoustic wave resonator in this example is substantially the same as that in the third example except that an isolation layer 21 is provided between the first electrode 11 and the first heat conduction layer 17. By providing the isolation layer 21, the leakage of electromagnetic wave signals can be effectively avoided, and the insertion loss is reduced.

In some examples, a material of the isolation layer 21 is preferably Si₃N₄, and alternatively SiO₂, Al₂O₃, etc., and a laminate formed by any combination thereof. A thickness of the isolation layer 21 is in a range from about 1 nm to 100 μm.

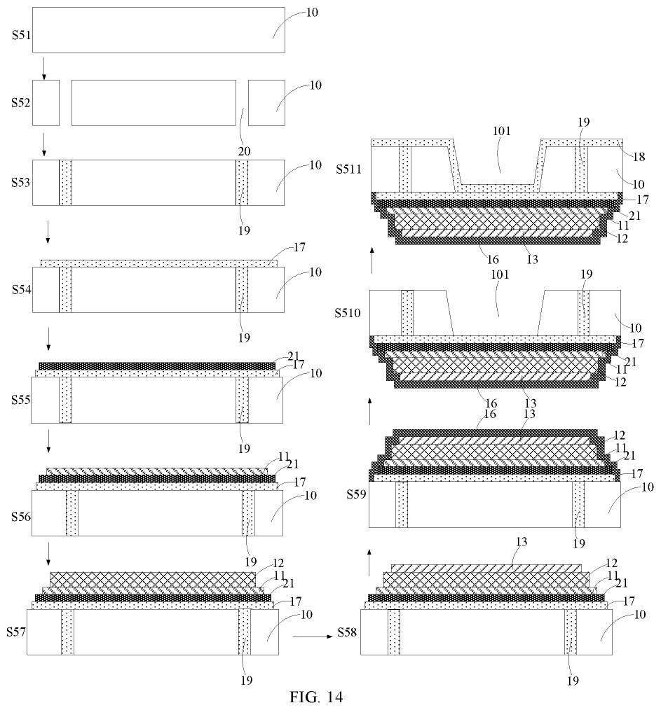

As shown in FIG. 14, a method for manufacturing the bulk acoustic wave resonator in the fifth example includes steps S51 to S411, wherein the steps S51 to S54 are respectively the same as the steps S31 to S34, and the steps S56 to S511 are respectively the same as the steps S35 to S310. Therefore, only step S55 will be described below.

Step S55 may include forming a film of the isolation layer 21 on a side of the base substrate 10 away from the first heat conduction layer 17, and depositing an electrical insulating material through a radio frequency magnetron sputtering, a pulsed laser sputtering (PLD), an atomic layer deposition (ALD), or a plasma enhanced chemical vapor deposition (PECVD). The isolation layer 21 is subjected to a photolithography process to form a pattern including the isolation layer 21, and the photolithography process includes coating glue (or spraying glue), pre-baking, exposing, developing and post-baking. An etching process is finally performed, and is preferably a wet etching process, or a dry etching process.

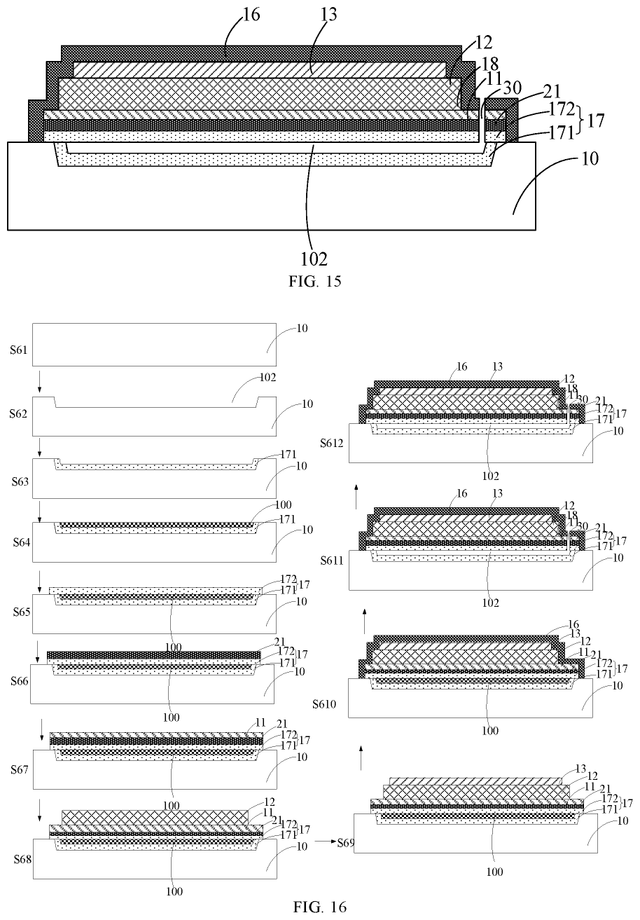

In a sixth example: FIG. 15 is a schematic diagram of a structure of a bulk acoustic wave resonator of a sixth example of an embodiment of the present disclosure. As shown in FIG. 15, the bulk acoustic wave resonator includes a base substrate 10, and a first heat conduction layer 17, an isolation layer 21, a first electrode 11, a piezoelectric layer 13, and a second electrode 13 which are sequentially disposed on the base substrate 10. The base substrate 10 includes a first groove. The base substrate includes a first surface (upper surface) and a second surface (lower surface) which are oppositely arranged along the thickness direction of the base substrate, an opening of the first groove is located in the first surface, the first electrode 11 is arranged on the first surface, and an orthographic projection of the first electrode 11 on a plane where the second surface is located covers the orthographic projection of the opening of the first groove on the plane where the second surface is located. The first heat conduction layer 17 includes a first heat conduction sub-layer 171 and a second heat conduction sub-layer 172; the first heat conduction sub-layer 171 is arranged in the first groove and covers a side wall and a bottom wall of the first groove; the second heat conduction sub-layer 172 is arranged between the base substrate 10 and the isolation layer 21, and the second heat conduction sub-layer 172 and the first heat conduction sub-layer defines an air gap 102 in the first groove; the second heat conduction sub-layer 172 is in contact with the isolation layer 21.

In some examples, an encapsulation layer 16 is further disposed on a side of the second electrode 13 away from the base substrate 10, to isolate the moisture and the oxygen and avoid the device damage.

In the bulk acoustic wave resonator in this example, the first heat conduction layer 17 is provided, and is in contact with the isolation layer 21, so that the heat generated by the device can be effectively guided to the base substrate 10 in time, and the device is prevented from failing due to a sharp temperature rise.

Next, a method of manufacturing the bulk acoustic wave resonator in the sixth example will be explained. As shown in FIG. 16, the manufacturing method specifically includes the following steps.

S61, providing a base substrate 10.

In some examples, the base substrate 10 may be a monocrystalline silicon substrate, or a glass, quartz, sapphire, SiC, GaAs, GaN, InP, BN, ZnO, or the like, and a thickness of the base substrate 10 is in a range from about 0.1 μm to about 10 mm.

The base substrate 10 is made of a monocrystalline silicon substrate, as an example, step S61 may specifically include: firstly, performing an ultrasonic cleaning on the monocrystalline silicon substrate with deionized water; then putting the monocrystalline silicon substrate into H₂SO₄:H₂O=3:1 mixed solution, heating to 250° C. and washing for 15 minutes; then putting the monocrystalline silicon substrate into deionized water for ultrasonic cleaning; then putting the monocrystalline silicon substrate into NH₄OH:H₂O=1:6, heating to 80° C. and washing for 15 minutes; taking out the monocrystalline silicon substrate and putting the monocrystalline silicon substrate into deionized water for washing; then putting the monocrystalline silicon substrate into HCl:H₂O₂:H₂O=1:1:5 mixed solution, heating to 85° C. and washing for 15 minutes; taking out the monocrystalline silicon substrate and putting the monocrystalline silicon substrate into dilute hydrofluoric acid of HF:H₂O=1:20 for rinsing for 10 seconds, to remove an oxide layer on a surface; and finally, putting the monocrystalline silicon substrate into deionized water for ultrasonic cleaning for 20 minutes, and drying the base substrate by using an air knife, to finish the cleaning process for the whole base substrate 10.

S62, providing a first groove in the base substrate 10.

In some examples, step S62 may specifically include: forming a mask pattern on the base substrate 10, and performing a photolithography process including coating glue (or spraying glue), pre-baking, exposing, developing and post-baking. Then, an etching process is performed, to form the first groove, and the etching process is preferably a wet etching process, or a dry etching process. Finally, a photoresist removing process is performed, so that the first groove has been formed.

S63, forming a first heat conduction sub-layer 171 of a first heat conduction layer 17 in the first groove, wherein the first heat conduction sub-layer 171 covers a bottom wall and a side wall of the first groove.

In some examples, a material of the first heat conduction sub-layer 171 is the same as the material of the first conductive layer 17. Step S63 may include depositing a first metal sub-film through preferably a direct current magnetron sputtering (or a radio frequency magnetron sputtering) or through a pulsed laser sputtering (PLD), a molecular beam epitaxy (MBE), a thermal evaporation, an electron beam evaporation process, or the like. In order to increase a thickness of the metal to facilitate the heat conduction, an electroplating thickening process may be performed. Then, a photolithography process is performed on the formed metal layer, including spraying glue (glue cannot be applied by a spin coating process due to a height difference between the air gap 102 and the substrate), pre-baking, exposing, developing and post-baking. An etching process is then performed, to form the first heat conduction sub-layer 171. The etching process is preferably a wet etching process, or a dry etching process. Finally, a photoresist removing process is performed, so that the first heat conduction sub-layer 171 has been formed.

S64, forming a sacrificial layer 100 on the first heat conduction sub-layer 171 in the first groove.

In some examples, a material of the sacrificial layer 100 may be a loose amorphous silicon dioxide doped with boron and phosphorus. Step S64 may specifically include: forming a slurry containing a loose silicon dioxide doped with boron and phosphorus through any one of a plasma enhanced chemical vapor deposition (PECVD), a sub-atmospheric pressure chemical vapor deposition (SACVD), and a screen printing; and then, performing a thermal annealing process at 700° C. to 900° C. for 15 minutes to 30 minutes in a vacuum chamber, so that a film of the loose amorphous silicon dioxide doped with boron and phosphorus is liquefied and flows, thereby completely filling and leveling pores in the first groove; and then performing cooling and curing processes; and finally, performing a chemical mechanical polishing process, that is, the base substrate 10 is pressed against a rough polishing pad by using a polishing head; the planarization of the surface of the base substrate 10 is realized by virtue of coupling effects such as polishing solution corrosion, particle friction, polishing pad friction or the like for a certain time; and a material overflowing from a surface of the first groove is subjected to a surface polish, so that a height of the material overflowing from a surface of the first groove is equal to a height of the surface of the base substrate 10.

S65, forming a second heat conduction sub-layer 172 on the base substrate 10.

In some examples, a material of the second heat conduction sub-layer 172 is the same as the material of the first heat conduction sub-layer 171. Step S65 may specifically include: depositing a second metal sub-film preferably by a direct current magnetron sputtering process (or a radio frequency magnetron sputtering process) or by a pulsed laser sputtering (PLD) process, a molecular beam epitaxy (MBE) process, a thermal evaporation process, an electron beam evaporation process, or the like; or by attaching a copper foil. In order to increase a thickness of the metal to facilitate the heat conduction, an electroplating thickening process may be performed. Then, a photolithography process is performed on the second metal sub-film, including coating glue (or spraying glue), pre-baking, exposing, developing and post-baking. An etching process is then performed, to form a pattern including the second heat conduction sub-layer 172. The etching process is preferably a wet etching process, or a dry etching process. Finally, a photoresist removing process is performed, so that the second heat conduction sub-layer 172 has been formed.

S66, forming an isolation layer 21 on a side of the second heat conduction sub-layer 172 away from the base substrate 10.

In some examples, a material of the isolation layer 21 is preferably Si₃N₄, and alternatively SiO₂, Al₂O₃, etc., and a laminate formed by any combination thereof. A thickness of the isolation layer 21 is in a range from about 1 nm to 100 μm.

Step S66 may specifically include: forming a film of the isolation layer 21 on a side of the second heat conduction sub-layer 172 away from the base substrate 10, and depositing an electrical insulating material through a radio frequency magnetron sputtering, a pulsed laser sputtering (PLD), an atomic layer deposition (ALD), or a plasma enhanced chemical vapor deposition (PECVD). The isolation layer 21 is subjected to a photolithography process to form a pattern including the isolation layer 21, and the photolithography process includes coating glue (or spraying glue), pre-baking, exposing, developing and post-baking. An etching process is finally performed, and is preferably a wet etching process, or a dry etching process.

S67, forming a first electrode 11 on a side of the isolation layer 21 away from the base substrate 10.

In some examples, a material of the first electrode 11 is a metal material, such as the metal Mo. The material of the first electrode 11 may alternatively be selected from metals such as Cu, Al, Co, Ag, Ti, Pt, Ru, W, Au, and alloys formed by any combination thereof. A thickness of the first electrode 11 is in a range from about 1 nm to 10 μm.

When the first electrode 11 is made of a metal material, the step S67 may include depositing a second metal film on the side of the isolation layer 21 away from the base substrate 10 preferably by a direct current magnetron sputtering process (or a radio frequency magnetron sputtering process) or by a pulsed laser sputtering (PLD) process, a molecular beam epitaxy (MBE) process, a thermal evaporation process, an electron beam evaporation process, or the like; or by attaching a copper foil. Then, a photolithography process is performed on the second metal film, including coating glue (or spraying glue), pre-baking, exposing, developing and post-baking. An etching process is then performed, to form a pattern including the first electrode 11, the etching process is preferably a wet etching process, or a dry etching process. Finally, a photoresist removing process is performed, so that the electrode 11 has been formed.

S68, forming a piezoelectric layer 13 on a side of the first electrode 11 away from the base substrate 10.

In some examples, a material of the piezoelectric layer 13 is a piezoelectric material, such as: AlN. Alternatively, the material of the piezoelectric layer 12 may be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, PVDF, etc. The piezoelectric layer 12 may be formed by one layer of the piezoelectric material, or may be formed by a stack of the above piezoelectric materials. A thickness of the piezoelectric layer 12 is in a range of 10 nm to 100 μm.

As an example, the piezoelectric layer 13 is an AlN single-layer structure, the step S68 may include forming a piezoelectric material layer on a side of the first electrode 11 away from the base substrate 10, and performing an orientation growth on the piezoelectric material layer preferably by radio frequency magnetron sputtering (or a direct current magnetron sputtering). A target material is selected as Al for the piezoelectric material of AlN. An AlN C-axis oriented piezoelectric material layer is formed by controlling an air pressure and a temperature of Ar and N₂ and a time and temperature of post-annealing in the deposition, and preferably the growth orientation is (001). The deposition process for the piezoelectric material layer may be selected from a pulsed laser sputtering (PLD), a molecular beam epitaxy (MBE), a metal organic chemical vapor deposition (MOCVD), a plasma enhanced chemical vapor deposition (PECVD), and the like. The piezoelectric layer 13 is subjected to a photolithography process including coating glue (or spraying glue), pre-baking, exposing, developing and post-baking. Then, the etching process is performed, to form a pattern of the piezoelectric layer 13. A preferred etching process may be a wet etching process or a dry etching process. Finally, a photoresist removing process is performed, so that the piezoelectric layer 13 has been formed.

S69, forming a second electrode 13 on a side of the piezoelectric layer 13 away from the first electrode 11.

In some examples, a material of the second electrode 13 may be selected from metal materials, such as Cu, Al, Mo, Co, Ag, Ti, Pt, Ru, W, Au, and alloys formed by any combination thereof. A thickness of the second electrode 13 is in a range from about 1 nm to 10 μm.

When the second electrode 13 is made of a metal material, step S69 may specifically include: depositing a third metal film on a side of the piezoelectric layer 13 away from the first electrode 11 through preferably a direct current magnetron sputtering (or a radio frequency magnetron sputtering) or through a pulsed laser sputtering (PLD), a molecular beam epitaxy (MBE), a thermal evaporation, an electron beam evaporation, or the like. Then, a photolithography process is performed on the third metal film, including coating glue (or spraying glue), pre-baking, exposing, developing and post-baking. An etching process is then performed, to form a pattern including the second electrode 13. The etching process is preferably a wet etching process, or a dry etching process. Finally, a photoresist removing process is performed, so that the second electrode 13 has been formed.

S610, forming an encapsulation layer 16 on a side of the second electrode 13 away from the base substrate 10.

In some examples, a material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

As an example, the material of the encapsulation layer 16 is the organic compound material, the step S610 may specifically include performing liquid coating of the organic material, such as spin coating, spraying, ink-jet printing, or transferring or the like, and then performing a heat curing process to form a pattern of the encapsulation layer 16.

S611, forming a release hole 30 extending through the encapsulation layer 16, the first electrode 11, the isolation layer 21 and the second heat conduction sub-layer 172.

In some examples, step S611 may specifically include: performing a photolithography process on a side of the encapsulation layer 16 away from the base substrate 10, including coating glue (or spraying glue), pre-baking, exposing, developing and post-baking, thereby exposing a hole; and then, performing a dry etching process, by preferably using a multi-step method, on the encapsulation layer 16, and then etching the first electrode 11 by replacing an etching gas, and then etching the isolation layer 21 by replacing an etching gas, and finally etching a second heat conduction sub-film by replacing an etching gas, where the etching process ends at the sacrificial layer 100; and finally performing a photoresist removing process, to form the release hole 30.

S612, removing the sacrificial layer 100.

In some examples, step S612 may include: etching the sacrificial layer 100 preferably through a wet etching process. An immersion etching process is performed by using a mixed etching solution of hydrofluoric acid, dilute nitric acid and deionized water (an etching temperature may be properly increased for improving a wet etching rate) for a sufficient time, thereby ensuring that the filling material of the silicon dioxide doped with boron and phosphorus in the air gap 102 is completely dissolved, and finally, an ultrasonic cleaning process is performed on the air gap 102 by using deionized water for multiple times, and the cleaned air gap 102 is dried, to form the air gap 102.

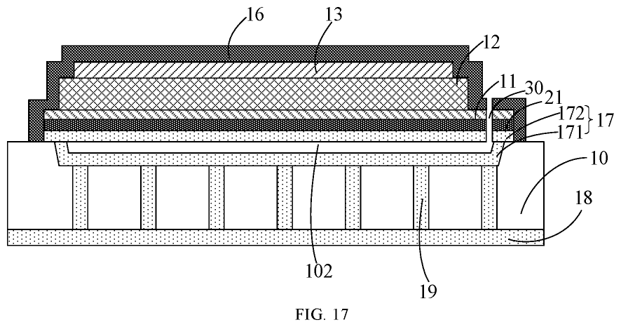

In a seventh example: FIG. 17 is a schematic diagram of a structure of a bulk acoustic wave resonator of a seventh example of an embodiment of the present disclosure. As shown in FIG. 17, the bulk acoustic wave resonator includes a base substrate 10, and a first heat conduction layer 17, an isolation layer 21, a first electrode 11, a piezoelectric layer 13, and a second electrode 13 which are sequentially disposed on the base substrate 10, and a second heat conduction layer 18 disposed on a side of the base substrate 10 away from the first electrode 11. The base substrate 10 includes a first groove and a plurality of heat conduction vias 20 extending through the base substrate 10 in a thickness direction of the base substrate 10. The base substrate includes a first surface (upper surface) and a second surface (lower surface) which are oppositely arranged along the thickness direction of the base substrate, an opening of the first groove is located in the first surface, the first electrode 11 is arranged on the first surface, and an orthographic projection of the first electrode 11 on a plane where the second surface is located covers the orthographic projection of the opening of the first groove on the plane where the second surface is located. The first heat conduction layer 17 includes a first heat conduction sub-layer 171 and a second heat conduction sub-layer 172; the first heat conduction sub-layer 171 is arranged in the first groove and covers a side wall and a bottom wall of the first groove; the second heat conduction sub-layer 172 is arranged between the base substrate 10 and the isolation layer 21, and the second heat conduction sub-layer 172 and the first heat conduction sub-layer defines an air gap 102 in the first groove; the second heat conduction sub-layer 172 is in contact with the isolation layer 21. The second heat conduction layer 18 covers the second surface of the base substrate 10. A heat conduction electrode 19 is arranged in each of the heat conduction vias 20, one end of the heat conduction electrode 19 is in contact with the first heat conduction layer 17, and the other end of the heat conduction electrode 19 is in contact with the second heat conduction layer 18.

In some examples, an encapsulation layer 16 is further disposed on a side of the second electrode 13 away from the base substrate 10, to isolate the moisture and the oxygen and avoid the device damage.

In the bulk acoustic wave resonator in this example, the first heat conduction layer 17 and the second heat conduction layer 18 are provided, the first heat conduction layer 17 is in contact with the isolation layer 21, and the second heat conduction layer 18 is in contact with the first heat conduction layer 17. The heat generated by the device can be timely guided by the heat conduction electrode 19 through the first heat conduction layer 17 to the second heat conduction layer 18, and then the heat is guided by the second heat conduction layer 18 to a board to be bonded later, so that the device is prevented from failing due to a sharp temperature rise. The heat is guided out through the heat conduction electrode 19, so that the defect can be overcome that the base substrate 10 is low in heat conductivity and poor in heat dissipation effect.

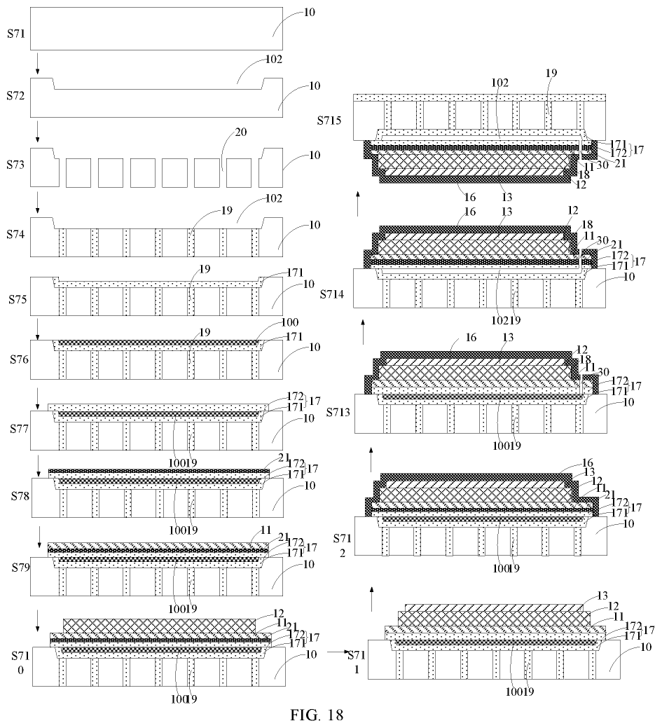

Next, a method for manufacturing the bulk acoustic wave resonator in the seventh example will be explained. As shown in FIG. 18, the manufacturing method specifically includes the following steps.

S71, providing a base substrate 10.

In some examples, the base substrate 10 may be a monocrystalline silicon substrate, or a glass, quartz, sapphire, SiC, GaAs, GaN, InP, BN, ZnO, or the like, and a thickness of the base substrate 10 is in a range from about 0.1 μm to about 10 mm.

The base substrate 10 is made of a monocrystalline silicon substrate, as an example, step S71 may specifically include: firstly, performing an ultrasonic cleaning on the monocrystalline silicon substrate with deionized water; then putting the monocrystalline silicon substrate into H₂SO₄:H₂O=3:1 mixed solution, heating to 250° C. and washing for 15 minutes; then putting the monocrystalline silicon substrate into deionized water for ultrasonic cleaning; then putting the monocrystalline silicon substrate into NH₄OH:H₂O=1:6, heating to 80° C. and washing for 15 minutes; taking out the monocrystalline silicon substrate and putting the monocrystalline silicon substrate into deionized water for washing; then putting the monocrystalline silicon substrate into HCl:H₂O₂:H₂O=1:1:5 mixed solution, heating to 85° C. and washing for 15 minutes; taking out the monocrystalline silicon substrate and putting the monocrystalline silicon substrate into dilute hydrofluoric acid of HF:H₂O=1:20 for rinsing for 10 seconds, to remove an oxide layer on a surface; and finally, putting the monocrystalline silicon substrate into deionized water for ultrasonic cleaning for 20 minutes, and drying the base substrate by using an air knife, to finish the cleaning process for the whole base substrate 10.

S72, providing a first groove in the base substrate 10.

In some examples, step S72 may specifically include: forming a mask pattern on the base substrate 10, and performing a photolithography process including coating glue (or spraying glue), pre-baking, exposing, developing and post-baking. Then, an etching process is performed, to form the first groove, and the etching process is preferably a wet etching process, or a dry etching process. Finally, a photoresist removing process is performed, so that the first groove has been formed.

S73, forming a plurality of heat conduction vias 20 extending through the base substrate 10 in a thickness direction of the base substrate 10 in the base substrate 10.

In some examples, step S73 may include forming the plurality of heat conduction vias 20 extending through the base substrate 10 in the thickness direction of the base substrate 10 in the base substrate 10 by using a sand blasting method, a photosensitive glass method, a focus discharging method, a plasma etching method, a laser ablation method, an electrochemical method, a laser induced etching method, or the like.

S74, forming a heat conduction electrode 19 in each heat conduction via 20.

In some examples, a material of the heat conduction electrode 19 may be the same as that of the first heat conduction layer 17. Step S74 may include forming a seed layer on a wall of the formed heat conduction via 20 through a magnetron sputtering, a thermal evaporation, an electron beam evaporation, and the spraying of a chemical plating medium; then, performing a metal hole filling and thickening processes, so that the metal is filled in the via. Optional methods of the metal hole filling and thickening process include electroplating, chemical plating, metal paste extrusion and thermocuring sintering or infrared laser irradiation sintering. Finally, the substrate is pressed against a rough polishing pad by using a polishing head; the planarization of the surface of the substrate is realized by virtue of coupling effects such as polishing solution corrosion, particle friction, polishing pad friction or the like for a certain time; and a material overflowing from a surface of the heat conduction via 20 is subjected to a surface polish, so that a height of the material overflowing from a surface of the heat conduction via 20 is equal to a height of the surface of the base substrate 10, and thus, the heat conduction electrode 19 has been formed.

S75, forming a first heat conduction sub-layer 171 of a first heat conduction layer 17 in the first groove, wherein the first heat conduction sub-layer 171 covers a bottom wall and a side wall of the first groove.

In some examples, a material of the first heat conduction sub-layer 171 is the same as the material of the first conductive layer 17. Step S75 may include depositing a first metal sub-film through preferably a direct current magnetron sputtering (or a radio frequency magnetron sputtering) or through a pulsed laser sputtering (PLD), a molecular beam epitaxy (MBE), a thermal evaporation, an electron beam evaporation process, or the like. In order to increase a thickness of the metal to facilitate the heat conduction, an electroplating thickening process may be performed. Then, a photolithography process is performed on the formed metal layer, including spraying glue (glue cannot be applied by a spin coating process due to a height difference between the air gap 102 and the substrate), pre-baking, exposing, developing and post-baking. An etching process is then performed, to form the first heat conduction sub-layer 171. The etching process is preferably a wet etching process, or a dry etching process. Finally, a photoresist removing process is performed, so that the first heat conduction sub-layer 171 has been formed.

S76, forming a sacrificial layer 100 on the first heat conduction sub-layer 171 in the first groove.

In some examples, a material of the sacrificial layer 100 may be a loose amorphous silicon dioxide doped with boron and phosphorus. Step S76 may specifically include: forming a slurry containing a loose silicon dioxide doped with boron and phosphorus through any one of a plasma enhanced chemical vapor deposition (PECVD), a sub-atmospheric pressure chemical vapor deposition (SACVD), and a screen printing; and then, performing a thermal annealing process at 700°C. to 900° C. for 15 minutes to 30 minutes in a vacuum chamber, so that a film of the loose amorphous silicon dioxide doped with boron and phosphorus is liquefied and flows, thereby completely filling and leveling pores in the first groove; and then performing cooling and curing processes; and finally, performing a chemical mechanical polishing process, that is, the base substrate 10 is pressed against a rough polishing pad by using a polishing head; the planarization of the surface of the base substrate 10 is realized by virtue of coupling effects such as polishing solution corrosion, particle friction, polishing pad friction or the like for a certain time; and a material overflowing from a surface of the first groove is subjected to a surface polish, so that a height of the material overflowing from a surface of the first groove is equal to a height of the surface of the base substrate 10.

S77, forming a second heat conduction sub-layer 172 on the base substrate 10.

In some examples, a material of the second heat conduction sub-layer 172 is the same as the material of the first heat conduction sub-layer 171. Step S77 may specifically include: depositing a second metal sub-film through preferably a direct current magnetron sputtering (or a radio frequency magnetron sputtering) or through a pulsed laser sputtering (PLD), a molecular beam epitaxy (MBE), a thermal evaporation, an electron beam evaporation process, or the like; or by attaching a copper foil. In order to increase a thickness of the metal to facilitate the heat conduction, an electroplating thickening process may be performed. Then, a photolithography process is performed on the second metal sub-film, including coating glue (or spraying glue), pre-baking, exposing, developing and post-baking. An etching process is then performed, to form a pattern including the second heat conduction sub-layer 172. The etching process is preferably a wet etching process, or a dry etching process. Finally, a photoresist removing process is performed, so that the second heat conduction sub-layer 172 has been formed.

S78, forming an isolation layer 21 on a side of the second heat conduction sub-layer 172 away from the base substrate 10.

In some examples, a material of the isolation layer 21 is preferably Si₃N₄, and alternatively SiO₂, Al₂O₃, etc., and a laminate formed by any combination thereof. A thickness of the isolation layer 21 is in a range from about 1 nm to 100 μm.

Step S78 may specifically include: forming a film of the isolation layer 21 on the side of the second heat conduction sub-layer 172 away from the base substrate 10, and depositing an electrical insulating material through a radio frequency magnetron sputtering, a pulsed laser sputtering (PLD), an atomic layer deposition (ALD), or a plasma enhanced chemical vapor deposition (PECVD). The isolation layer 21 is subjected to a photolithography process to form a pattern including the isolation layer 21, and the photolithography process includes coating glue (or spraying glue), pre-baking, exposing, developing and post-baking. An etching process is finally performed, and is preferably a wet etching process, or a dry etching process.

S79, forming a first electrode 11 on a side of the isolation layer 21 away from the base substrate 10.

In some examples, a material of the first electrode 11 is a metal material, such as the metal Mo. The material of the first electrode 11 may alternatively be selected from metals such as Cu, Al, Co, Ag, Ti, Pt, Ru, W, Au, and alloys formed by any combination thereof. A thickness of the first electrode 11 is in a range from about 1 nm to 10 μm.

When the first electrode 11 is made of a metal material, the step S79 may include depositing a second metal film on a side of the isolation layer 21 away from the base substrate 10 preferably by a direct current magnetron sputtering process (or a radio frequency magnetron sputtering process) or by a pulsed laser sputtering (PLD) process, a molecular beam epitaxy (MBE) process, a thermal evaporation process, an electron beam evaporation process, or the like; or by attaching a copper foil. Then, a photolithography process is performed on the second metal film, including coating glue (or spraying glue), pre-baking, exposing, developing and post-baking. An etching process is then performed, to form a pattern including the first electrode 11, and the etching process is preferably a wet etching process, or a dry etching process. Finally, a photoresist removing process is performed, so that the electrode 11 has been formed.

S710, forming a piezoelectric layer 13 on a side of the first electrode 11 away from the base substrate 10.

In some examples, a material of the piezoelectric layer 13 is a piezoelectric material, such as: AlN. Alternatively, the material of the piezoelectric layer 12 may be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, PVDF, etc. The piezoelectric layer 12 may be formed by one layer of the piezoelectric material, or may be formed by a stack of the above piezoelectric materials. A thickness of the piezoelectric layer 12 is in a range of 10 nm to 100 μm.

As an example, the piezoelectric layer 13 is an AlN single-layer structure, the step S710 may include forming a piezoelectric material layer on a side of the first electrode 11 away from the base substrate 10, and performing an orientation growth on the piezoelectric material layer preferably by radio frequency magnetron sputtering (or a direct current magnetron sputtering). A target material is selected as Al for the piezoelectric material of AlN. An AlN C-axis oriented piezoelectric material layer is formed by controlling an air pressure and a temperature of Ar and N₂ and a time and temperature of post-annealing in the deposition, and preferably the growth orientation is (001). The deposition process for the piezoelectric material layer may be selected from a pulsed laser sputtering (PLD), a molecular beam epitaxy (MBE), a metal organic chemical vapor deposition (MOCVD), a plasma enhanced chemical vapor deposition (PECVD), and the like. The piezoelectric layer 13 is subjected to a photolithography process including coating glue (or spraying glue), pre-baking, exposing, developing and post-baking. Then, the etching process is performed, to form a pattern of the piezoelectric layer 13. A preferred etching process may be a wet etching process or a dry etching process. Finally, a photoresist removing process is performed, so that the piezoelectric layer 13 has been formed.

S711, forming a second electrode 13 on a side of the piezoelectric layer 13 away from the first electrode 11.

In some examples, a material of the second electrode 13 may be selected from metal materials, such as Cu, Al, Mo, Co, Ag, Ti, Pt, Ru, W, Au, and alloys formed by any combination thereof. A thickness of the second electrode 13 is in a range from about 1 nm to 10 μm.

When the second electrode 13 is made of a metal material, step S711 may specifically include: depositing a third metal film on a side of the piezoelectric layer 13 away from the first electrode 11 through preferably a direct current magnetron sputtering (or a radio frequency magnetron sputtering) or through a pulsed laser sputtering (PLD), a molecular beam epitaxy (MBE), a thermal evaporation, an electron beam evaporation, or the like. Then, a photolithography process is performed on the third metal film, including coating glue (or spraying glue), pre-baking, exposing, developing and post-baking. An etching process is then performed, to form a pattern including the second electrode 13. The etching process is preferably a wet etching process, or a dry etching process. Finally, a photoresist removing process is performed, so that the second electrode 13 has been formed.

S712, forming an encapsulation layer 16 on a side of the second electrode 13 away from the base substrate 10.

In some examples, a material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

As an example, the material of the encapsulation layer 16 is the organic compound material, the step S712 may specifically include performing liquid coating of the organic material, such as spin coating, spraying, ink-jet printing, or transferring or the like, and then performing a heat curing process to form a pattern of the encapsulation layer 16.

S713, forming a release hole 30 extending through the encapsulation layer 16, the first electrode 11, the isolation layer 21 and the second heat conduction sub-layer 172.

In some examples, step S713 may specifically include: performing a photolithography process on a side of the encapsulation layer 16 away from the base substrate 10, including coating glue (or spraying glue), pre-baking, exposing, developing and post-baking, thereby exposing a hole; and then, performing a dry etching process, by preferably using a multi-step method, on the encapsulation layer 16, and then etching the first electrode 11 by replacing an etching gas, and then etching the isolation layer 21 by replacing an etching gas, and finally etching a second heat conduction sub-film by replacing an etching gas, where the etching process ends at the sacrificial layer 100; and finally performing a photoresist removing process, to form the release hole 30.

S714, removing the sacrificial layer 100.

In some examples, step S714 may include: etching the sacrificial layer 100 preferably through a wet etching process. An immersion etching process is performed by using a mixed etching solution of hydrofluoric acid, dilute nitric acid and deionized water (an etching temperature may be properly increased for improving a wet etching rate) for a sufficient time, thereby ensuring that the filling material of the silicon dioxide doped with boron and phosphorus in the air gap 102 is completely dissolved, and finally, an ultrasonic cleaning process is performed on the air gap 102 by using deionized water for multiple times, and the cleaned air gap 102 is dried, to form the air gap 102.

S715, turning over the base substrate 10 with the above structure, and forming a second heat conduction layer 18.

In some examples, the materials of the second heat conduction layer 18 and the first heat conduction layer 17 may be the same. The step S715 may specifically include: depositing a fourth metal film on the base substrate 10 through preferably a direct current magnetron sputtering (or a radio frequency magnetron sputtering) or through a pulsed laser sputtering (PLD), a molecular beam epitaxy (MBE), a thermal evaporation, an electron beam evaporation, or the like; or by attaching a copper foil. In order to increase a thickness of the metal to facilitate the heat conduction, an electroplating thickening process may be performed. Then, a photolithography process is performed on the fourth metal film layer, including coating glue (or spraying glue), pre-baking, exposing, developing and post-baking. An etching process is then performed, to form a pattern including the second heat conduction layer, and the etching process is preferably a wet etching process, or a dry etching process. Finally, a photoresist removing process is performed, so that the second heat conduction layer 18 has been formed.

It should be noted that, a part of the second heat conduction layer 18 is a metal pad area bonding to a circuit board, to transfer heat generated by the device to the circuit board in time.

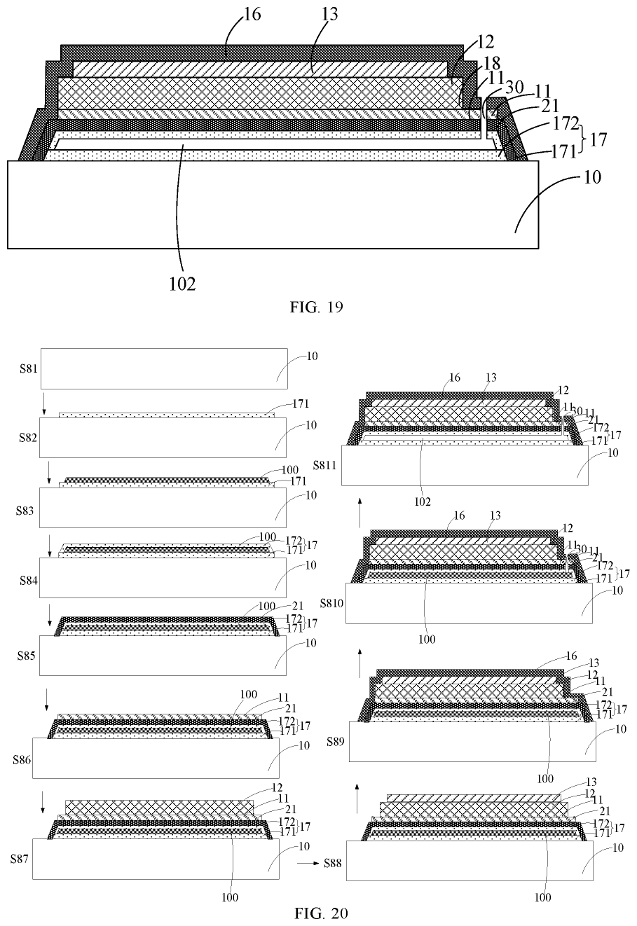

In an eighth example: FIG. 19 is a schematic diagram of a structure of a bulk acoustic wave resonator of an eighth example of an embodiment of the present disclosure. As shown in FIG. 19, the bulk acoustic wave resonator includes a base substrate 10, and a first heat conduction layer 17, an isolation layer 21, a first electrode 11, a piezoelectric layer 13, and a second electrode 13 which are sequentially disposed on the base substrate 10. A space is defined between the isolation layer 21 and the base substrate 10, that is, the isolation layer 21 is groove-shaped and is opened to the base substrate 10. The first heat conduction layer 17 includes a first heat conduction sub-layer 171 and a second heat conduction sub-layer 172; the first heat conduction sub-layer 171 is disposed on the base substrate 10, and the second heat conduction sub-layer 172 is disposed on a surface of the isolation layer 21 close to the base substrate 10, and the second heat conduction sub-layer 172 and the first heat conduction sub-layer 171 defines an air gap 102.

In some examples, an encapsulation layer 16 is further disposed on a side of the second electrode 13 away from the base substrate 10, to isolate the moisture and the oxygen and avoid the device damage.

In the bulk acoustic wave resonator in this example, the first heat conduction layer 17 is provided, and is in contact with the isolation layer 21, so that the heat generated by the device can be effectively guided to the base substrate 10 in time, and the device is prevented from failing due to a sharp temperature rise.

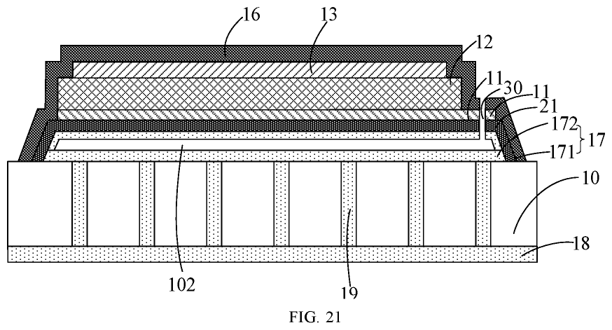

Next, a method of manufacturing the bulk acoustic wave resonator in the eighth example will be explained. As shown in FIG. 20, the manufacturing method specifically includes the following steps.

S81, providing a base substrate 10.

In some examples, the base substrate 10 may be a monocrystalline silicon substrate, or a glass, quartz, sapphire, SiC, GaAs, GaN, InP, BN, ZnO, or the like, and a thickness of the base substrate 10 is in a range from about 0.1 μm to about 10 mm.

The base substrate 10 is made of a monocrystalline silicon substrate, as an example, step S81 may specifically include: firstly, performing an ultrasonic cleaning on the monocrystalline silicon substrate with deionized water; then putting the monocrystalline silicon substrate into H₂SO₄:H₂O=3:1 mixed solution, heating to 250° C. and washing for 15 minutes; then putting the monocrystalline silicon substrate into deionized water for ultrasonic cleaning; then putting the monocrystalline silicon substrate into NH₄OH:H₂O=1:6, heating to 80° C. and washing for 15 minutes; taking out the monocrystalline silicon substrate and putting the monocrystalline silicon substrate into deionized water for washing; then putting the monocrystalline silicon substrate into HCl:H₂O₂:H₂O=1:1:5 mixed solution, heating to 85° C. and washing for 15 minutes; taking out the monocrystalline silicon substrate and putting the monocrystalline silicon substrate into dilute hydrofluoric acid of HF:H₂O=1:20 for rinsing for 10 seconds, to remove an oxide layer on a surface; and finally, putting the monocrystalline silicon substrate into deionized water for ultrasonic cleaning for 20 minutes, and drying the base substrate by using an air knife, to finish the cleaning process for the whole base substrate 10.

S82, forming a first heat conduction sub-layer 171 of a first heat conduction layer 17 on the base substrate 10.

In some examples, a material of the first heat conduction sub-layer 171 is the same as the material of the first conductive layer 17. Step S82 may include depositing a first metal sub-film through preferably a direct current magnetron sputtering (or a radio frequency magnetron sputtering) or through a pulsed laser sputtering (PLD), a molecular beam epitaxy (MBE), a thermal evaporation, an electron beam evaporation, or the like. In order to increase a thickness of the metal to facilitate the heat conduction, an electroplating thickening process may be performed. Then, a photolithography process is performed on the formed metal layer, including spraying glue (glue cannot be applied by a spin coating process due to a height difference between the air gap 102 and the substrate), pre-baking, exposing, developing and post-baking. An etching process is then performed, to form the first heat conduction sub-layer 171. The etching process is preferably a wet etching process, or a dry etching process. Finally, a photoresist removing process is performed, so that the first heat conduction sub-layer 171 has been formed.

S83, forming a sacrificial layer 100 on the first heat conduction sub-layer 171 in the first groove.

In some examples, a material of the sacrificial layer 100 may be a loose amorphous silicon dioxide doped with boron and phosphorus. Step S83 may specifically include: forming a film containing a loose silicon dioxide doped with boron and phosphorus as the sacrificial layer 100 through a plasma enhanced chemical vapor deposition (PECVD) or a sub-atmospheric pressure chemical vapor deposition (SACVD); and performing a photolithography process on a material of the sacrificial layer 100, including coating glue (or spraying glue), pre-baking, exposing, developing and post-baking. Finally, an etching process is performed, to form a pattern of the sacrificial layer 100. The etching process is a wet etching process, preferably a dry etching process.

S84, forming a second heat conduction sub-layer 172 on the base substrate 10.

In some examples, a material of the second heat conduction sub-layer 172 is the same as the material of the first heat conduction sub-layer 171. Step S84 may specifically include: depositing a second metal sub-film through preferably a direct current magnetron sputtering (or a radio frequency magnetron sputtering) or through a pulsed laser sputtering (PLD), a molecular beam epitaxy (MBE), a thermal evaporation, an electron beam evaporation, or the like; or by attaching a copper foil. In order to increase a thickness of the metal to facilitate the heat conduction, an electroplating thickening process may be performed. Then, a photolithography process is performed on the second metal sub-film, including coating glue (or spraying glue), pre-baking, exposing, developing and post-baking. An etching process is then performed, to form a pattern including the second heat conduction sub-layer 172. The etching process is preferably a wet etching process, or a dry etching process. Finally, a photoresist removing process is performed, so that the second heat conduction sub-layer 172 has been formed.

S85, forming an isolation layer 21 on a side of the second heat conduction sub-layer 172 away from the base substrate 10.

In some examples, a material of the isolation layer 21 is preferably Si₃N₄, and alternatively SiO₂, Al₂O₃, etc., and a laminate formed by any combination thereof. A thickness of the isolation layer 21 is in a range from about 1 nm to 100 μm.

Step S85 may specifically include: forming a film of the isolation layer 21 on the side of the second heat conduction sub-layer 172 away from the base substrate 10, and depositing an electrical insulating material through a radio frequency magnetron sputtering, a pulsed laser sputtering (PLD), an atomic layer deposition (ALD), or a plasma enhanced chemical vapor deposition (PECVD). The isolation layer 21 is subjected to a photolithography process to form a pattern including the isolation layer 21, and the photolithography process includes coating glue (or spraying glue), pre-baking, exposing, developing and post-baking. An etching process is finally performed, and is preferably a wet etching process, or a dry etching process.

S86, forming a first electrode 11 on a side of the isolation layer 21 away from the base substrate 10.

In some examples, a material of the first electrode 11 is a metal material, such as the metal Mo. The material of the first electrode 11 may alternatively be selected from metals such as Cu, Al, Co, Ag, Ti, Pt, Ru, W, Au, and alloys formed by any combination thereof. A thickness of the first electrode 11 is in a range from about 1 nm to 10 μm.

When the first electrode 11 is made of a metal material, the step S86 may include depositing a second metal film on a side of the isolation layer 21 away from the base substrate 10 preferably by a direct current magnetron sputtering process (or a radio frequency magnetron sputtering process) or by a pulsed laser sputtering (PLD) process, a molecular beam epitaxy (MBE) process, a thermal evaporation process, an electron beam evaporation process, or the like; or by attaching a copper foil. Then, a photolithography process is performed on the second metal film, including coating glue (or spraying glue), pre-baking, exposing, developing and post-baking. An etching process is then performed, to form a pattern including the first electrode 11, and the etching process is preferably a wet etching process, or a dry etching process. Finally, a photoresist removing process is performed, so that the electrode 11 has been formed.

S87, forming a piezoelectric layer 13 on a side of the first electrode 11 away from the base substrate 10.

In some examples, a material of the piezoelectric layer 13 is a piezoelectric material, such as: AlN. Alternatively, the material of the piezoelectric layer 12 may be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, PVDF, etc. The piezoelectric layer 12 may be formed by one layer of the piezoelectric material, or may be formed by a stack of the above piezoelectric materials. A thickness of the piezoelectric layer 12 is in a range of 10 nm to 100 μm.

As an example, the piezoelectric layer 13 is an AlN single-layer structure, the step S87 may include forming a piezoelectric material layer on a side of the first electrode 11 away from the base substrate 10, and performing an orientation growth on the piezoelectric material layer preferably by radio frequency magnetron sputtering (or a direct current magnetron sputtering). A target material is selected as Al for the piezoelectric material of AlN. An AlN C-axis oriented piezoelectric material layer is formed by controlling an air pressure and a temperature of Ar and N₂ and a time and temperature of post-annealing in the deposition, and preferably the growth orientation is (001). The deposition process for the piezoelectric material layer may be selected from a pulsed laser sputtering (PLD), a molecular beam epitaxy (MBE), a metal organic chemical vapor deposition (MOCVD), a plasma enhanced chemical vapor deposition (PECVD), and the like. The piezoelectric layer 13 is subjected to a photolithography process including coating glue (or spraying glue), pre-baking, exposing, developing and post-baking. Then, the etching process is performed, to form a pattern of the piezoelectric layer 13. A preferred etching process may be a wet etching process or a dry etching process. Finally, a photoresist removing process is performed, so that the piezoelectric layer 13 has been formed.

S88, forming a second electrode 13 on a side of the piezoelectric layer 13 away from the first electrode 11.

In some examples, a material of the second electrode 13 may be selected from metal materials, such as Cu, Al, Mo, Co, Ag, Ti, Pt, Ru, W, Au, and alloys formed by any combination thereof. A thickness of the second electrode 13 is in a range from about 1 nm to 10 μm.

When the second electrode 13 is made of a metal material, step S88 may specifically include: depositing a third metal film on a side of the piezoelectric layer 13 away from the first electrode 11 through preferably a direct current magnetron sputtering (or a radio frequency magnetron sputtering) or through a pulsed laser sputtering (PLD), a molecular beam epitaxy (MBE), a thermal evaporation, an electron beam evaporation, or the like. Then, a photolithography process is performed on the third metal film, including coating glue (or spraying glue), pre-baking, exposing, developing and post-baking. An etching process is then performed, to form a pattern including the second electrode 13. The etching process is preferably a wet etching process, or a dry etching process. Finally, a photoresist removing process is performed, so that the second electrode 13 has been formed.

S89, forming an encapsulation layer 16 on a side of the second electrode 13 away from the base substrate 10.

In some examples, a material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

As an example, the material of the encapsulation layer 16 is the organic compound material, the step S89 may specifically include performing liquid coating of the organic material, such as spin coating, spraying, ink-jet printing, or transferring or the like, and then performing a heat curing process to form a pattern of the encapsulation layer 16.

S810, forming a release hole 30 extending through the encapsulation layer 16, the first electrode 11, the isolation layer 21 and the second heat conduction sub-layer 172.

In some examples, step S810 may specifically include: performing a photolithography process on a side of the encapsulation layer 16 away from the base substrate 10, including coating glue (or spraying glue), pre-baking, exposing, developing and post-baking, thereby exposing a hole; and then, performing a dry etching process, by preferably using a multi-step method, on the encapsulation layer 16, and then etching the first electrode 11 by replacing an etching gas, and then etching the isolation layer 21 by replacing an etching gas, and finally etching a second heat conduction sub-film by replacing an etching gas, where the etching process ends at the sacrificial layer 100; and finally performing a photoresist removing process, to form the release hole 30.

S811, removing the sacrificial layer 100.

In some examples, step S811 may include: etching the sacrificial layer 100 preferably through a wet etching process. An immersion etching process is performed by using a mixed etching solution of hydrofluoric acid, dilute nitric acid and deionized water (an etching temperature may be properly increased for improving a wet etching rate) for a sufficient time, thereby ensuring that the filling material of the silicon dioxide doped with boron and phosphorus in the air gap 102 is completely dissolved, and finally, an ultrasonic cleaning process is performed on the air gap 102 by using deionized water for multiple times, and the cleaned air gap 102 is dried, to form the air gap 102.

In a ninth example: FIG. 21 is a schematic diagram of a structure of a bulk acoustic wave resonator of a ninth example of an embodiment of the present disclosure. As shown in FIG. 21, the bulk acoustic wave resonator includes a base substrate 10, and a first heat conduction layer 17, an isolation layer 21, a first electrode 11, a piezoelectric layer 13, and a second electrode 13 which are sequentially disposed on the base substrate 10, and a second heat conduction layer 18 disposed on a side of the base substrate 10 away from the first heat conduction layer 17. A space is defined between the isolation layer 21 and the base substrate 10, that is, the isolation layer 21 is groove-shaped and is opened to the base substrate 10. The first heat conduction layer 17 includes a first heat conduction sub-layer 171 and a second heat conduction sub-layer 172; the first heat conduction sub-layer 171 is disposed on the base substrate 10, and the second heat conduction sub-layer 172 is disposed on a surface of the isolation layer 21 close to the base substrate 10, and the second heat conduction sub-layer 172 and the first heat conduction sub-layer 171 defines an air gap 102. The base substrate 10 includes a plurality of heat conduction vias 20 extending through the base substrate 10 in a thickness direction of the base substrate 10. The bulk acoustic wave resonator further includes a heat conduction electrode 19 arranged in each heat conduction via, one end of the heat conduction electrode 19 is in contact with the first heat conduction sub-layer 171, and the other end of the heat conduction electrode 19 is in contact with the second heat conduction layer 18.

In some examples, an encapsulation layer 16 is further disposed on a side of the second electrode 13 away from the base substrate 10, to isolate the moisture and the oxygen and avoid the device damage.

In the bulk acoustic wave resonator in this example the first heat conduction layer 17 and the second heat conduction layer 18 are provided, the first heat conduction layer 17 is in contact with the isolation layer 21, and the second heat conduction layer 18 is in contact with the first heat conduction layer 17. The heat generated by the device can be timely guided by the heat conduction electrode 19 through the first heat conduction layer 17 to the second heat conduction layer 18, and then the heat is guided by the second heat conduction layer 18 to a board to be bonded later, so that the device is prevented from failing due to a sharp temperature rise. The heat is guided out through the heat conduction electrode 19, so that the defect can be overcome that the base substrate 10 is low in heat conductivity and poor in heat dissipation effect.

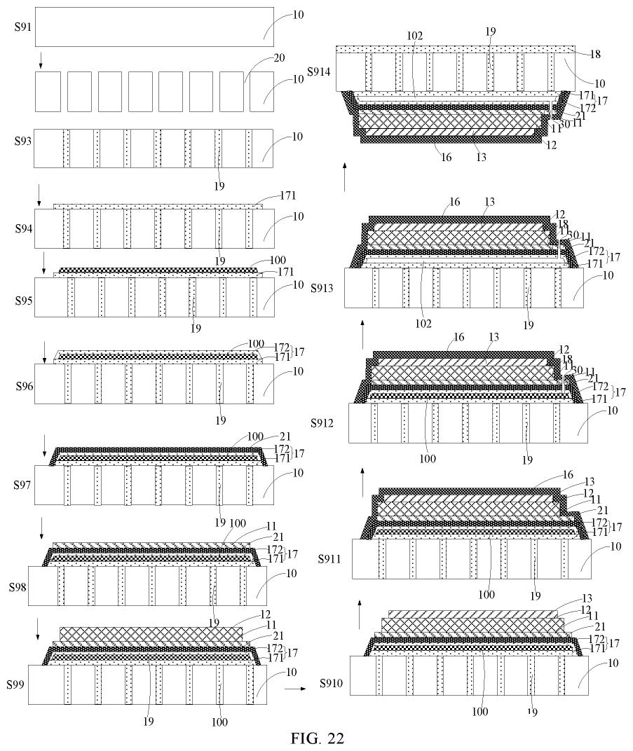

Next, a method for manufacturing the bulk acoustic wave resonator in the ninth example will be explained. As shown in FIG. 22, the manufacturing method specifically includes the following steps.

S91, providing a base substrate 10.

In some examples, the base substrate 10 may be a monocrystalline silicon substrate, or a glass, quartz, sapphire, SiC, GaAs, GaN, InP, BN, ZnO, or the like, and a thickness of the base substrate 10 is in a range from about 0.1 μm to about 10 mm.

The base substrate 10 is made of a monocrystalline silicon substrate, as an example, step S91 may specifically include: firstly, performing an ultrasonic cleaning on the monocrystalline silicon substrate with deionized water; then putting the monocrystalline silicon substrate into H₂SO₄:H₂O=3:1 mixed solution, heating to 250° C. and washing for 15 minutes; then putting the monocrystalline silicon substrate into deionized water for ultrasonic cleaning; then putting the monocrystalline silicon substrate into NH₄OH:H₂O=1:6, heating to 80° C. and washing for 15 minutes; taking out the monocrystalline silicon substrate and putting the monocrystalline silicon substrate into deionized water for washing; then putting the monocrystalline silicon substrate into HCl:H₂O₂:H₂O=1:1:5 mixed solution, heating to 85° C. and washing for 15 minutes; taking out the monocrystalline silicon substrate and putting the monocrystalline silicon substrate into dilute hydrofluoric acid of HF:H₂O=1:20 for rinsing for 10 seconds, to remove an oxide layer on a surface; and finally, putting the monocrystalline silicon substrate into deionized water for ultrasonic cleaning for 20 minutes, and drying the base substrate by using an air knife, to finish the cleaning process for the whole base substrate 10.

S92, forming a plurality of heat conduction vias 20 extending through the base substrate 10 in a thickness direction of the base substrate 10 in the base substrate 10.

In some examples, step S92 may include forming the plurality of heat conduction vias 20 extending through the base substrate 10 in the thickness direction of the base substrate 10 in the base substrate 10 by using a sand blasting method, a photosensitive glass method, a focus discharging method, a plasma etching method, a laser ablation method, an electrochemical method, a laser induced etching method, or the like.

S93, forming a heat conduction electrode 19 in each heat conduction via 20.

In some examples, a material of the heat conduction electrode 19 may be the same as that of the first heat conduction layer 17. Step S93 may include forming a seed layer on a wall of the formed heat conduction via 20 through a magnetron sputtering, a thermal evaporation, an electron beam evaporation, and the spraying of a chemical plating medium; then, performing a metal hole filling and thickening processes, so that the metal is filled in the via. Optional methods of the metal hole filling and thickening process include electroplating, chemical plating, metal paste extrusion and thermocuring sintering or infrared laser irradiation sintering. Finally, the substrate is pressed against a rough polishing pad by using a polishing head; the planarization of the surface of the substrate is realized by virtue of coupling effects such as polishing solution corrosion, particle friction, polishing pad friction or the like for a certain time; and a material overflowing from a surface of the heat conduction via 20 is subjected to a surface polish, so that a height of the material overflowing from a surface of the heat conduction via 20 is equal to a height of the surface of the base substrate 10, and thus, the heat conduction electrode 19 has been formed.

S94, forming a first heat conduction sub-layer 171 of a first heat conduction layer 17 on the base substrate 10.

In some examples, a material of the first heat conduction sub-layer 171 is the same as the material of the first conductive layer 17. Step S94 may include depositing a first metal sub-film through preferably a direct current magnetron sputtering (or a radio frequency magnetron sputtering) or through a pulsed laser sputtering (PLD), a molecular beam epitaxy (MBE), a thermal evaporation, an electron beam evaporation process, or the like. In order to increase a thickness of the metal to facilitate the heat conduction, an electroplating thickening process may be performed. Then, a photolithography process is performed on the formed metal layer, including spraying glue (glue cannot be applied by a spin coating process due to a height difference between the air gap 102 and the substrate), pre-baking, exposing, developing and post-baking. An etching process is then performed, to form the first heat conduction sub-layer 171. The etching process is preferably a wet etching process, or a dry etching process. Finally, a photoresist removing process is performed, so that the first heat conduction sub-layer 171 has been formed.

S95, forming a sacrificial layer 100 on the first heat conduction sub-layer 171 in the first groove.

In some examples, a material of the sacrificial layer 100 may be a loose amorphous silicon dioxide doped with boron and phosphorus. Step S95 may specifically include: forming a film containing a loose silicon dioxide doped with boron and phosphorus as the sacrificial layer 100 through a plasma enhanced chemical vapor deposition (PECVD) or a sub-atmospheric pressure chemical vapor deposition (SACVD); and performing a photolithography process on a material of the sacrificial layer 100, including coating glue (or spraying glue), pre-baking, exposing, developing and post-baking. Finally, an etching process is performed, to form a pattern of the sacrificial layer 100. The etching process is a wet etching process, preferably a dry etching process.

S96, forming a second heat conduction sub-layer 172 on the base substrate 10.

In some examples, a material of the second heat conduction sub-layer 172 is the same as the material of the first heat conduction sub-layer 171. Step S96 may specifically include: depositing a second metal sub-film preferably by a direct current magnetron sputtering process (or a radio frequency magnetron sputtering process) or by a pulsed laser sputtering (PLD) process, a molecular beam epitaxy (MBE) process, a thermal evaporation process, an electron beam evaporation process, or the like; or by attaching a copper foil. In order to increase a thickness of the metal to facilitate the heat conduction, an electroplating thickening process may be performed. Then, a photolithography process is performed on the second metal sub-film, including coating glue (or spraying glue), pre-baking, exposing, developing and post-baking. An etching process is then performed, to form a pattern including the second heat conduction sub-layer 172. The etching process is preferably a wet etching process, or a dry etching process. Finally, a photoresist removing process is performed, so that the second heat conduction sub-layer 172 has been formed.

S97, forming an isolation layer 21 on a side of the second heat conduction sub-layer 172 away from the base substrate 10.

In some examples, a material of the isolation layer 21 is preferably Si₃N₄, and alternatively SiO₂, Al₂O₃, etc., and a laminate formed by any combination thereof. A thickness of the isolation layer 21 is in a range from about 1 nm to 100 μm.

Step S97 may specifically include: forming a film of the isolation layer 21 on the side of the second heat conduction sub-layer 172 away from the base substrate 10, and depositing an electrical insulating material through a radio frequency magnetron sputtering, a pulsed laser sputtering (PLD), an atomic layer deposition (ALD), or a plasma enhanced chemical vapor deposition (PECVD). The isolation layer 21 is subjected to a photolithography process to form a pattern including the isolation layer 21, and the photolithography process includes coating glue (or spraying glue), pre-baking, exposing, developing and post-baking. An etching process is finally performed, and is preferably a wet etching process, or a dry etching process.

S98, forming a first electrode 11 on a side of the isolation layer 21 away from the base substrate 10.

In some examples, a material of the first electrode 11 is a metal material, such as the metal Mo. The material of the first electrode 11 may alternatively be selected from metals such as Cu, Al, Co, Ag. Ti, Pt, Ru, W, Au, and alloys formed by any combination thereof. A thickness of the first electrode 11 is in a range from about 1 nm to 10 μm.

When the first electrode 11 is made of a metal material, the step S98 may include depositing a second metal film on a side of the isolation layer 21 away from the base substrate 10 preferably by a direct current magnetron sputtering process (or a radio frequency magnetron sputtering process) or by a pulsed laser sputtering (PLD) process, a molecular beam epitaxy (MBE) process, a thermal evaporation process, an electron beam evaporation process, or the like; or by attaching a copper foil. Then, a photolithography process is performed on the second metal film, including coating glue (or spraying glue), pre-baking, exposing, developing and post-baking. An etching process is then performed, to form a pattern including the first electrode 11, and the etching process is preferably a wet etching process, or a dry etching process. Finally, a photoresist removing process is performed, so that the electrode 11 has been formed.

S99, forming a piezoelectric layer 13 on a side of the first electrode 11 away from the base substrate 10.

In some examples, a material of the piezoelectric layer 13 is a piezoelectric material, such as: AlN. Alternatively, the material of the piezoelectric layer 12 may be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, PVDF, etc. The piezoelectric layer 12 may be formed by one layer of the piezoelectric material, or may be formed by a stack of the above piezoelectric materials. A thickness of the piezoelectric layer 12 is in a range of 10 nm to 100 μm.

As an example, the piezoelectric layer 13 is an AlN single-layer structure, the step S99 may include forming a piezoelectric material layer on a side of the first electrode 11 away from the base substrate 10, and performing an orientation growth on the piezoelectric material layer preferably by radio frequency magnetron sputtering (or a direct current magnetron sputtering). A target material is selected as Al for the piezoelectric material of AlN. An AlN C-axis oriented piezoelectric material layer is formed by controlling an air pressure and a temperature of Ar and N₂ and a time and temperature of post-annealing in the deposition, and preferably the growth orientation is (001). The deposition process for the piezoelectric material layer may be selected from a pulsed laser sputtering (PLD), a molecular beam epitaxy (MBE), a metal organic chemical vapor deposition (MOCVD), a plasma enhanced chemical vapor deposition (PECVD), and the like. The piezoelectric layer 13 is subjected to a photolithography process including coating glue (or spraying glue), pre-baking, exposing, developing and post-baking. Then, the etching process is performed, to form a pattern of the piezoelectric layer 13. A preferred etching process may be a wet etching process or a dry etching process. Finally, a photoresist removing process is performed, so that the piezoelectric layer 13 has been formed.

S910, forming a second electrode 13 on a side of the piezoelectric layer 13 away from the first electrode 11.

In some examples, a material of the second electrode 13 may be selected from metal materials, such as Cu, Al, Mo, Co, Ag, Ti, Pt, Ru, W, Au, and alloys formed by any combination thereof. A thickness of the second electrode 13 is in a range from about 1 nm to 10 μm.

When the second electrode 13 is made of a metal material, step S910 may specifically include: depositing a third metal film on a side of the piezoelectric layer 13 away from the first electrode 11 through preferably a direct current magnetron sputtering (or a radio frequency magnetron sputtering) or through a pulsed laser sputtering (PLD), a molecular beam epitaxy (MBE), a thermal evaporation, an electron beam evaporation, or the like. Then, a photolithography process is performed on the third metal film, including coating glue (or spraying glue), pre-baking, exposing, developing and post-baking. An etching process is then performed, to form a pattern including the second electrode 13. The etching process is preferably a wet etching process, or a dry etching process. Finally, a photoresist removing process is performed, so that the second electrode 13 has been formed.

S911, forming an encapsulation layer 16 on a side of the second electrode 13 away from the base substrate 10.

In some examples, a material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

As an example, the material of the encapsulation layer 16 is the organic compound material, the step S911 may specifically include performing liquid coating of the organic material, such as spin coating, spraying, ink-jet printing, or transferring or the like, and then performing a heat curing process to form a pattern of the encapsulation layer 16.

S912, forming a release hole 30 extending through the encapsulation layer 16, the first electrode 11, the isolation layer 21 and the second heat conduction sub-layer 172.

In some examples, step S912 may specifically include: performing a photolithography process on a side of the encapsulation layer 16 away from the base substrate 10, including coating glue (or spraying glue), pre-baking, exposing, developing and post-baking, thereby exposing a hole; and then, performing a dry etching process, by preferably using a multi-step method, on the encapsulation layer 16, and then etching the first electrode 11 by replacing an etching gas, and then etching the isolation layer 21 by replacing an etching gas, and finally etching a second heat conduction sub-film by replacing an etching gas, where the etching process ends at the sacrificial layer 100; and finally performing a photoresist removing process, to form the release hole 30.

S913, removing the sacrificial layer 100.

In some examples, step S913 may include: etching the sacrificial layer 100 preferably through a wet etching process. An immersion etching process is performed by using a mixed etching solution of hydrofluoric acid, dilute nitric acid and deionized water (an etching temperature may be properly increased for improving a wet etching rate) for a sufficient time, thereby ensuring that the filling material of the silicon dioxide doped with boron and phosphorus in the air gap 102 is completely dissolved, and finally, an ultrasonic cleaning process is performed on the air gap 102 by using deionized water for multiple times, and the cleaned air gap 102 is dried, to form the air gap 102

S914, turning over the base substrate 10 with the above structure, and forming a second heat conduction layer 18.

In some examples, the materials of the second heat conduction layer 18 and the first heat conduction layer 17 may be the same. The step S914 may specifically include: depositing a fourth metal film on the base substrate 10 through preferably a direct current magnetron sputtering (or a radio frequency magnetron sputtering) or through a pulsed laser sputtering (PLD), a molecular beam epitaxy (MBE), a thermal evaporation, an electron beam evaporation, or the like; or by attaching a copper foil. In order to increase a thickness of the metal to facilitate the heat conduction, an electroplating thickening process may be performed. Then, a photolithography process is performed on the fourth metal film layer, including coating glue (or spraying glue), pre-baking, exposing, developing and post-baking. An etching process is then performed, to form a pattern including the second heat conduction layer, and the etching process is preferably a wet etching process, or a dry etching process. Finally, a photoresist removing process is performed, so that the second heat conduction layer 18 has been formed.

It should be noted that a part of the second heat conduction layer 18 is a metal pad area bonded to the circuit board, to transfer heat generated by the device to a circuit board in time.

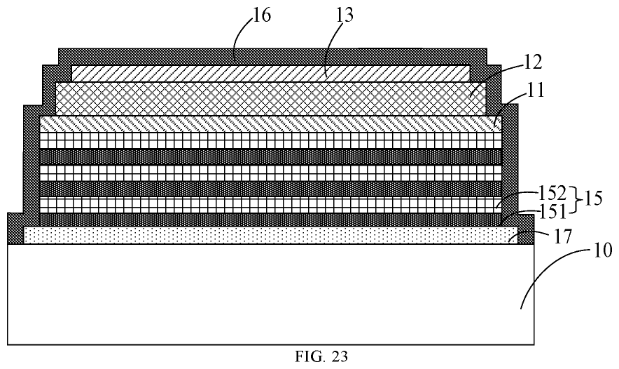

In a tenth example, FIG. 23 is a schematic diagram of a structure of a bulk acoustic wave resonator of a tenth example of an embodiment of the present disclosure. As shown in FIG. 23, the bulk acoustic wave resonator includes a base substrate 10, and a first heat conduction layer 17, at least one acoustic mirror structure 15, a first electrode 11, a piezoelectric layer 13, and a second electrode 13 which are sequentially disposed on the base substrate 10. Each mirror structure 15 includes a first sub-structure and a second sub-structure sequentially arranged along a direction away from the base substrate 10, and an acoustic impedance of a material of the first sub-structure is greater than that of a material of the second sub-structure. For ease of description and understanding, the first sub-structure will be referred to hereinafter as a high acoustic impedance layer 151 and the second sub-structure as a low acoustic impedance layer 152.

In some examples, an encapsulation layer 16 is further disposed on a side of the second electrode 13 away from the base substrate 10, to isolate the moisture and the oxygen and avoid the device damage.

In the bulk acoustic wave resonator in this example the first heat conduction layer 17 is provided, and the first heat conduction layer 17 is in contact with the mirror structure, so that the heat generated by the device can be effectively guided to the base substrate 10 in time, and the device is prevented from failing due to a sharp temperature rise.

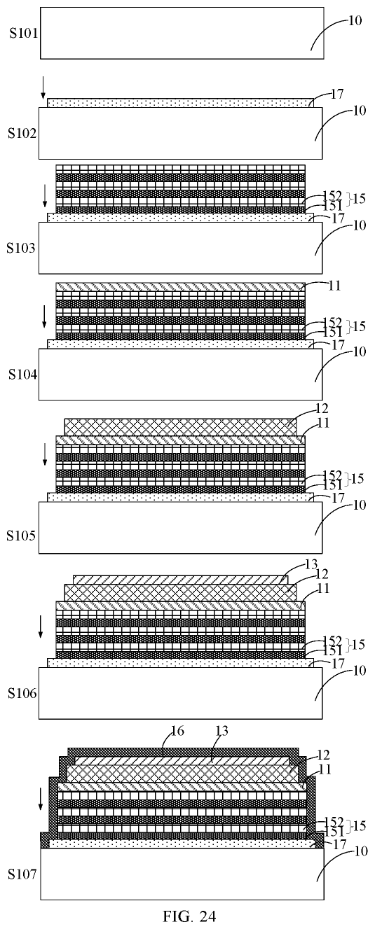

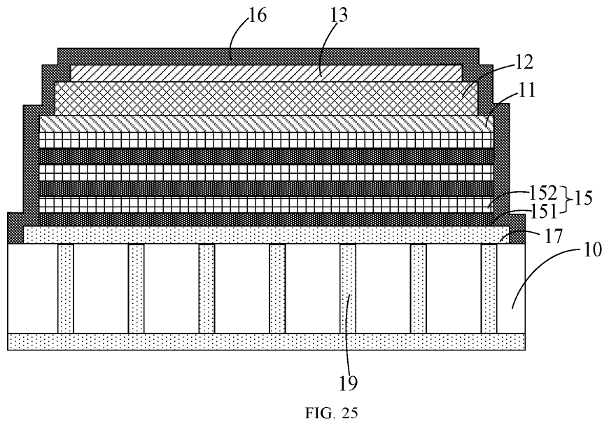

Next, a method of manufacturing the bulk acoustic wave resonator in the tenth example will be explained. As shown in FIG. 24, the manufacturing method specifically includes the following steps.

S101, providing a base substrate 10.

In some examples, the base substrate 10 may be a monocrystalline silicon substrate, or a glass, quartz, sapphire, SiC, GaAs, GaN, InP, BN, ZnO, or the like, and a thickness of the base substrate 10 is in a range from about 0.1 μm to about 10 mm.

The base substrate 10 is made of a monocrystalline silicon substrate, as an example, step S101 may specifically include: firstly, performing an ultrasonic cleaning on the monocrystalline silicon substrate with deionized water; then putting the monocrystalline silicon substrate into H₂SO₄:H₂O=3:1 mixed solution, heating to 250° C. and washing for 15 minutes; then putting the monocrystalline silicon substrate into deionized water for ultrasonic cleaning; then putting the monocrystalline silicon substrate into NH₄OH:H₂O=1:6, heating to 80° C. and washing for 15 minutes; taking out the monocrystalline silicon substrate and putting the monocrystalline silicon substrate into deionized water for washing; then putting the monocrystalline silicon substrate into HCl:H₂O₂:H₂O=1:1:5 mixed solution, heating to 85° C. and washing for 15 minutes; taking out the monocrystalline silicon substrate and putting the monocrystalline silicon substrate into dilute hydrofluoric acid of HF:H₂O=1:20 for rinsing for 10 seconds, to remove an oxide layer on a surface; and finally, putting the monocrystalline silicon substrate into deionized water for ultrasonic cleaning for 20 minutes, and drying the base substrate by using an air knife, to finish the cleaning process for the whole base substrate 10.

S102, forming a first heat conduction layer 17 on the base substrate 10.

In some examples, a material of the first heat conduction layer 17 is a metal material, such as the metal Cu which has a high thermal conductivity. The material of the first heat conduction layer 17 may alternatively be selected from metals such as Al, Mo, Co, Ag, Ti, Pt, Ru, W, Au, and alloys formed by any combination thereof, and a thickness of the first heat conduction layer 17 is in a range from about 10 nm to 50 μm.

When the first heat conduction layer 17 is made of a metal material, the step S102 may specifically include: depositing a first metal film on the base substrate 10 preferably by a direct current magnetron sputtering process (or a radio frequency magnetron sputtering process) or by a pulsed laser sputtering (PLD) process, a molecular beam epitaxy (MBE) process, a thermal evaporation process, an electron beam evaporation process, or the like; or by attaching a copper foil. In order to increase a thickness of the metal to facilitate the heat conduction, an electroplating thickening process may be performed. Then, a photolithography process is performed on the first metal film layer, including coating glue (or spraying glue), pre-baking, exposing, developing and post-baking. An etching process is then performed, to form a pattern including the first heat conduction layer 17, and the etching process is preferably a wet etching process, or a dry etching process. Finally, a photoresist removing process is performed, so that the first heat conduction layer 17 has been formed.

S103, forming a mirror structure 15 on a side of the first heat conduction layer 17 away from the base substrate 10.

In some examples, the at least one acoustic mirror structure 15 is composed of high acoustic impedance layers 151 and low acoustic impedance layers 152 alternately arranged. An acoustic impedance of a material is equal to a propagation velocity of an acoustic wave in the material multiplied by a density of the material. Theoretically, when a thickness of each high acoustic impedance layer 151 is equal to a quarter of a wavelength of an acoustic wave at a resonant frequency of the bulk acoustic wave resonator propagating in the high acoustic impedance layer 151, and a thickness of each low acoustic impedance layer 152 is equal to a quarter of the wavelength of the acoustic wave at the resonant frequency of the bulk acoustic wave resonator propagating in the low acoustic impedance layer 152, the effect of the high acoustic impedance layers 151 and the low acoustic impedance layers 152 alternately arranged (high/low/high/low or low/high/low/high . . . ) is equivalent to an acoustic mirror, to reflect the acoustic wave signal leaking from the top. One high acoustic impedance layer 151 and one low acoustic impedance layer 152 as one group form one mirror structure 15, generally 3 groups or 4 groups of the high acoustic impedance layers 151 and the low acoustic impedance layers 152 are needed to achieve a better acoustic reflection effect. Certainly, the greater number of groups may achieve the better acoustic reflection effect, with the increased cost. The number of groups is not limited herein, and the number of the mirror structures 15 may be in a range of 1 to 100. There is no limitation on whether the thickness of each layer is equal to one quarter of the wavelength, and any thickness is acceptable. The high acoustic impedance layer 151 may be made of W, Ir, Pt, Ru, Au, Mo, Ta, Ti, Cu, Ni, Zn, Al, Al₂O₃, Ag, etc., and the common low acoustic impedance layer may be made of SiO₂, Si₃N₄, Mg, rubber, nylon, polyimide, polyethylene, polystyrene, Teflon, etc. The thickness of each high acoustic impedance layer 151 and each low acoustic impedance layer 152 is in a range from 1 nm to 10 μm depending on the different resonance frequencies and the acoustic velocities of different materials.

Step S103 may specifically include the following steps (a) and (b). In the step (a), a film material for a high acoustic impedance layer 151 is firstly deposited, preferably by direct current magnetron sputtering (alternatively, radio frequency magnetron sputtering), alternatively by pulsed laser sputtering (PLD), molecular beam epitaxy (MBE), thermal evaporation, electron beam evaporation; processes including coating glue (or spraying glue), pre-baking, exposing, developing, post-baking and etching are performed on the film for the high acoustic impedance layer 151 to form the high acoustic impedance layer 151. The etching process is preferably a wet etching process, or alternatively a dry etching process. In the step (b), a film material for a low acoustic impedance layer 152 is firstly deposited, preferably by direct current magnetron sputtering (alternatively, radio frequency magnetron sputtering), alternatively by pulsed laser sputtering (PLD), molecular beam epitaxy (MBE), thermal evaporation, electron beam evaporation; processes including coating glue (or spraying glue), pre-baking, exposing, developing, post-baking and etching are performed on the film for the low acoustic impedance layer 152 to form the low acoustic impedance layer 152. The etching process is preferably a wet etching process, or alternatively a dry etching process. Thereafter, the steps (a) and (b) are repeated until the at least one acoustic mirror structure 15 satisfying the design requirement on the number of layers is obtained.

S104, forming a first electrode 11 on a side of the first heat conduction layer 17 away from the base substrate 10.

In some examples, a material of the first electrode 11 is a metal material, such as the metal Mo. The material of the first electrode 11 may alternatively be selected from metals such as Cu, Al, Co, Ag. Ti, Pt, Ru, W, Au, and alloys formed by any combination thereof. A thickness of the first electrode 11 is in a range from about 1 nm to 10 μm.

When the first electrode 11 is made of a metal material, the step S104 may include depositing a second metal film on a side of the first heat conduction layer 17 away from the base substrate 10 through preferably a direct current magnetron sputtering (or a radio frequency magnetron sputtering) or through a pulsed laser sputtering (PLD), a molecular beam epitaxy (MBE), a thermal evaporation, an electron beam evaporation, or the like; or by attaching a copper foil. Then, a photolithography process is performed on the second metal film, including coating glue (or spraying glue), pre-baking, exposing, developing and post-baking. An etching process is then performed, to form a pattern including the first electrode 11, and the etching process is preferably a wet etching process, or a dry etching process. Finally, a photoresist removing process is performed, so that the electrode 11 has been formed.

S105, forming a piezoelectric layer 13 on a side of the first electrode 11 away from the base substrate 10.

In some examples, a material of the piezoelectric layer 13 is a piezoelectric material, such as: AlN. Alternatively, the material of the piezoelectric layer 12 may be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, PVDF, etc. The piezoelectric layer 12 may be formed by one layer of the piezoelectric material, or may be formed by a stack of the above piezoelectric materials. A thickness of the piezoelectric layer 12 is in a range of 10 nm to 100 μm.

As an example, the piezoelectric layer 13 is an AlN single-layer structure, the step S105 may include forming a piezoelectric material layer on a side of the first electrode 11 away from the base substrate 10, and performing an orientation growth on the piezoelectric material layer preferably by radio frequency magnetron sputtering (or a direct current magnetron sputtering). A target material is selected as Al for the piezoelectric material of AlN. An AlN C-axis oriented piezoelectric material layer is formed by controlling an air pressure and a temperature of Ar and N₂ and a time and temperature of post-annealing in the deposition, and preferably the growth orientation is (001). The deposition process for the piezoelectric material layer may be selected from a pulsed laser sputtering (PLD) process, a molecular beam epitaxy (MBE) process, a metal organic chemical vapor deposition (MOCVD) process, a plasma enhanced chemical vapor deposition (PECVD) process, and the like. The piezoelectric layer 13 is subjected to a photolithography process including coating glue (or spraying glue), pre-baking, exposing, developing and post-baking. Then, the etching process is performed, to form a pattern of the piezoelectric layer 13. A preferred etching process may be a wet etching process or a dry etching process. Finally, a photoresist removing process is performed, so that the piezoelectric layer 13 has been formed.

S106, forming a second electrode 13 on a side of the piezoelectric layer 13 away from the first electrode 11.

In some examples, a material of the second electrode 13 may be selected from metal materials, such as Cu, Al, Mo, Co, Ag, Ti, Pt, Ru, W, Au, and alloys formed by any combination thereof. A thickness of the second electrode 13 is in a range from about 1 nm to 10 μm.

When the second electrode 13 is made of a metal material, step S106 may specifically include: depositing a third metal film on a side of the piezoelectric layer 13 away from the first electrode 11 through preferably a direct current magnetron sputtering (or a radio frequency magnetron sputtering) or through a pulsed laser sputtering (PLD), a molecular beam epitaxy (MBE), a thermal evaporation, an electron beam evaporation, or the like. Then, a photolithography process is performed on the third metal film, including coating glue (or spraying glue), pre-baking, exposing, developing and post-baking. An etching process is then performed, to form a pattern including the second electrode 13. The etching process is preferably a wet etching process, or a dry etching process. Finally, a photoresist removing process is performed, so that the second electrode 13 has been formed.

S107, forming an encapsulation layer 16 on a side of the second electrode 13 away from the base substrate 10.

In some examples, a material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

As an example, the material of the encapsulation layer 16 is the organic compound material, the step S107 may specifically include performing liquid coating of the organic material, such as spin coating, spraying, ink-jet printing, or transferring or the like, and then performing a heat curing process to form a pattern of the encapsulation layer 16.

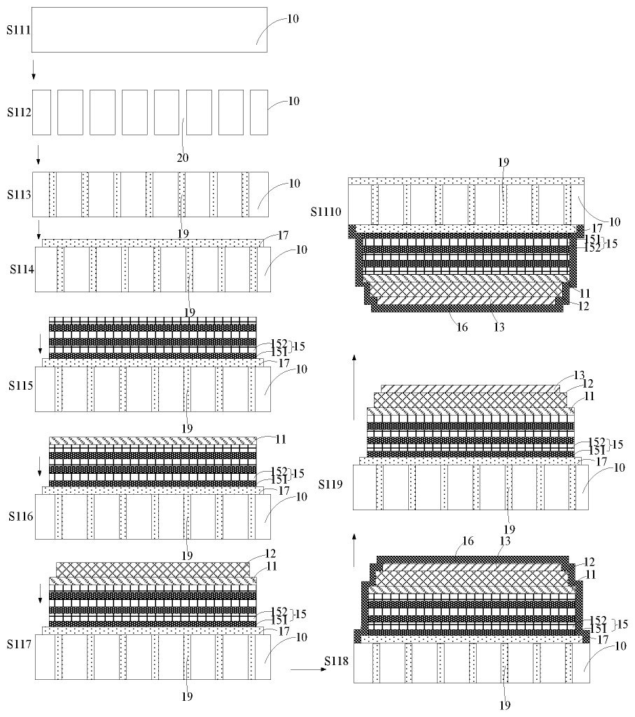

In an eleventh example: FIG. 25 is a schematic diagram of a structure of a bulk acoustic wave resonator of an eleventh example of an embodiment of the present disclosure. As shown in FIG. 25, the bulk acoustic wave resonator includes a base substrate 10, and a first heat conduction layer 17, at least one acoustic mirror structure 15, a first electrode 11, a piezoelectric layer 13, and a second electrode 13 which are sequentially disposed on the base substrate 10, and a second heat conduction layer 18 disposed on a side of the base substrate 10 away from the first heat conduction layer 17. The base substrate 10 includes a plurality of heat conduction vias 20 extending through the base substrate 10 in a thickness direction of the base substrate 10. The bulk acoustic wave resonator further includes a heat conduction electrode 19 arranged in each heat conduction via, one end of the heat conduction electrode 19 is in contact with the first heat conduction sub-layer 171, and the other end of the heat conduction electrode 19 is in contact with the second heat conduction layer 18. Each mirror structure 15 includes a first sub-structure and a second sub-structure sequentially arranged along a direction away from the base substrate 10, and an acoustic impedance of a material of the first sub-structure is greater than that of a material of the second sub-structure. For ease of description and understanding, the first sub-structure will be referred to hereinafter as a high acoustic impedance layer 151 and the second sub-structure as a low acoustic impedance layer 152.

In some examples, an encapsulation layer 16 is further disposed on a side of the second electrode 13 away from the base substrate 10, to isolate the moisture and the oxygen and avoid the device damage.

In the bulk acoustic wave resonator in this example, the first heat conduction layer 17 and the second heat conduction layer 18 are provided, the first heat conduction layer 17 is in contact with the mirror structure 15, and the second heat conduction layer 18 is in contact with the first heat conduction layer 17. The heat generated by the device can be timely guided by the heat conduction electrode 19 through the first heat conduction layer 17 to the second heat conduction layer 18, and then the heat is guided by the second heat conduction layer 18 to a board to be bonded later, so that the device is prevented from failing due to a sharp temperature rise. The heat is guided out through the heat conduction electrode 19, so that the defect can be overcome that the base substrate 10 is low in heat conductivity and poor in heat dissipation effect.

Next, a method for manufacturing the bulk acoustic wave resonator in the eleventh example will be explained. As shown in FIG. 26, the manufacturing method specifically includes the following steps.

S111, providing a base substrate 10.

In some examples, the base substrate 10 may be a monocrystalline silicon substrate, or a glass, quartz, sapphire, SiC, GaAs, GaN, InP, BN, ZnO, or the like, and a thickness of the base substrate 10 is in a range from about 0.1 μm to about 10 mm.

The base substrate 10 is made of a monocrystalline silicon substrate, as an example, step S111 may specifically include: firstly, performing an ultrasonic cleaning on the monocrystalline silicon substrate with deionized water; then putting the monocrystalline silicon substrate into H₂SO₄:H₂O=3:1 mixed solution, heating to 250° C. and washing for 15 minutes; then putting the monocrystalline silicon substrate into deionized water for ultrasonic cleaning; then putting the monocrystalline silicon substrate into NH₄OH:H₂O=1:6, heating to 80° C. and washing for 15 minutes; taking out the monocrystalline silicon substrate and putting the monocrystalline silicon substrate into deionized water for washing; then putting the monocrystalline silicon substrate into HCl:H₂O₂:H₂O=1:1:5 mixed solution, heating to 85° C. and washing for 15 minutes; taking out the monocrystalline silicon substrate and putting the monocrystalline silicon substrate into dilute hydrofluoric acid of HF:H₂O=1:20 for rinsing for 10 seconds, to remove an oxide layer on a surface; and finally, putting the monocrystalline silicon substrate into deionized water for ultrasonic cleaning for 20 minutes, and drying the base substrate by using an air knife, to finish the cleaning process for the whole base substrate 10.

S112, forming a plurality of heat conduction vias 20 extending through the base substrate 10 in a thickness direction of the base substrate 10 in the base substrate 10.

In some examples, step S112 may include forming the plurality of heat conduction vias 20 extending through the base substrate 10 in the thickness direction of the base substrate 10 in the base substrate 10 by using a sand blasting method, a photosensitive glass method, a focus discharging method, a plasma etching method, a laser ablation method, an electrochemical method, a laser induced etching method, or the like.

S113, forming a heat conduction electrode 19 in each heat conduction via 20.

In some examples, a material of the heat conduction electrode 19 may be the same as that of the first heat conduction layer 17. Step S113 may include forming a seed layer on a wall of the formed heat conduction via 20 through a magnetron sputtering, a thermal evaporation, an electron beam evaporation, and the spraying of a chemical plating medium; then, performing a metal hole filling and thickening processes, so that the metal is filled in the via. Optional methods of the metal hole filling and thickening process include electroplating, chemical plating, metal paste extrusion and thermocuring sintering or infrared laser irradiation sintering. Finally, the substrate is pressed against a rough polishing pad by using a polishing head; the planarization of the surface of the substrate is realized by virtue of coupling effects such as polishing solution corrosion, particle friction, polishing pad friction or the like for a certain time; and a material overflowing from a surface of the heat conduction via 20 is subjected to a surface polish, so that a height of the material overflowing from a surface of the heat conduction via 20 is equal to a height of the surface of the base substrate 10, and thus, the heat conduction electrode 19 has been formed.

S114, forming a first heat conduction layer 17 on the base substrate 10.

In some examples, a material of the first heat conduction layer 17 is a metal material, such as the metal Cu which has a high thermal conductivity. The material of the first heat conduction layer 17 may alternatively be selected from metals such as Al, Mo, Co, Ag. Ti, Pt, Ru, W, Au, and alloys formed by any combination thereof, and a thickness of the first heat conduction layer 17 is in a range from about 10 nm to 50 μm.

When the first heat conduction layer 17 is made of a metal material, the step S114 may specifically include: depositing a first metal film on the base substrate 10 preferably by a direct current magnetron sputtering process (or a radio frequency magnetron sputtering process) or by a pulsed laser sputtering (PLD) process, a molecular beam epitaxy (MBE) process, a thermal evaporation process, an electron beam evaporation process, or the like; or by attaching a copper foil. In order to increase a thickness of the metal to facilitate the heat conduction, an electroplating thickening process may be performed. Then, a photolithography process is performed on the first metal film layer, including coating glue (or spraying glue), pre-baking, exposing, developing and post-baking. An etching process is then performed, to form a pattern including the first heat conduction layer 17, the etching process is preferably a wet etching process, or a dry etching process. Finally, a photoresist removing process is performed, so that the first heat conduction layer 17 has been formed.

S115, forming a mirror structure 15 on a side of the first heat conduction layer 17 away from the base substrate 10.

In some examples, the at least one acoustic mirror structure 15 is composed of high acoustic impedance layers 151 and low acoustic impedance layers 152 alternately arranged. An acoustic impedance of a material is equal to a propagation velocity of an acoustic wave in the material multiplied by a density of the material. Theoretically, when a thickness of each high acoustic impedance layer 151 is equal to a quarter of a wavelength of an acoustic wave at a resonant frequency of the bulk acoustic wave resonator propagating in the high acoustic impedance layer 151, and a thickness of each low acoustic impedance layer 152 is equal to a quarter of the wavelength of the acoustic wave at the resonant frequency of the bulk acoustic wave resonator propagating in the low acoustic impedance layer 152, the effect of the high acoustic impedance layers 151 and the low acoustic impedance layers 152 alternately arranged (high/low/high/low or low/high/low/high . . . ) is equivalent to an acoustic mirror, to reflect the acoustic wave signal leaking from the top. One high acoustic impedance layer 151 and one low acoustic impedance layer 152 as one group form one mirror structure 15, generally 3 groups or 4 groups of the high acoustic impedance layers 151 and the low acoustic impedance layers 152 are needed to achieve a better acoustic reflection effect. Certainly, the greater number of groups may achieve the better acoustic reflection effect, with the increased cost. The number of groups is not limited herein, and the number of the mirror structures 15 may be in a range of 1 to 100. There is no limitation on whether the thickness of each layer is equal to one quarter of the wavelength, and any thickness is acceptable. The high acoustic impedance layer 151 may be made of W, Ir, Pt, Ru, Au, Mo, Ta, Ti, Cu, Ni, Zn, Al, Al₂O₃, Ag, etc., and the common low acoustic impedance layer may be made of SiO₂, Si₃N₄, Mg, rubber, nylon, polyimide, polyethylene, polystyrene, Teflon, etc. The thickness of each high acoustic impedance layer 151 and each low acoustic impedance layer 152 is in a range from 1 nm to 10 μm depending on the different resonance frequencies and the acoustic velocities of different materials.

Step S115 may specifically include the following steps (a) and (b). In the step (a), a film material for a high acoustic impedance layer 151 is firstly deposited, preferably by direct current magnetron sputtering process (alternatively, a radio frequency magnetron sputtering process), alternatively by a pulsed laser sputtering (PLD) process, a molecular beam epitaxy (MBE) process, a thermal evaporation process, an electron beam evaporation process; processes including coating glue (or spraying glue), pre-baking, exposing, developing, post-baking and etching are performed on the film for the high acoustic impedance layer 151 to form the high acoustic impedance layer 151. The etching process is preferably a wet etching process, or alternatively a dry etching process. In the step (b), a film material for a low acoustic impedance layer 152 is firstly deposited, preferably by direct current magnetron sputtering (alternatively, radio frequency magnetron sputtering), alternatively by a pulsed laser sputtering (PLD) process, a molecular beam epitaxy (MBE) process, a thermal evaporation process, an electron beam evaporation process; processes including coating glue (or spraying glue), pre-baking, exposing, developing, post-baking and etching are performed on the film for the low acoustic impedance layer 152 to form the low acoustic impedance layer 152. The etching process is preferably a wet etching process, or alternatively a dry etching process. Thereafter, the steps (a) and (b) are repeated until the at least one acoustic mirror structure 15 satisfying the design requirement on the number of layers is obtained.

S116, forming a first electrode 11 on a side of the first heat conduction layer 17 away from the base substrate 10.

In some examples, a material of the first electrode 11 is a metal material, such as the metal Mo. The material of the first electrode 11 may alternatively be selected from metals such as Cu, Al, Co, Ag, Ti, Pt, Ru, W, Au, and alloys formed by any combination thereof. A thickness of the first electrode 11 is in a range from about 1 nm to 10 μm.

When the first electrode 11 is made of a metal material, the step S116 may include depositing a second metal film on a side of the first heat conduction layer 17 away from the base substrate 10 preferably by a direct current magnetron sputtering process (or a radio frequency magnetron sputtering process) or by a pulsed laser sputtering (PLD) process, a molecular beam epitaxy (MBE) process, a thermal evaporation process, an electron beam evaporation process, or the like; or by attaching a copper foil. Then, a photolithography process is performed on the second metal film, including coating glue (or spraying glue), pre-baking, exposing, developing and post-baking. An etching process is then performed, to form a pattern including the first electrode 11, and the etching process is preferably a wet etching process or a dry etching process. Finally, a photoresist removing process is performed, so that the electrode 11 has been formed.

S117, forming a piezoelectric layer 13 on a side of the first electrode 11 away from the base substrate 10.

In some examples, a material of the piezoelectric layer 13 is a piezoelectric material, such as: AlN. Alternatively, the material of the piezoelectric layer 12 may be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, PVDF, etc. The piezoelectric layer 12 may be formed by one layer of the piezoelectric material, or may be formed by a stack of the above piezoelectric materials. A thickness of the piezoelectric layer 12 is in a range of 10 nm to 100 μm.

As an example, the piezoelectric layer 13 is an AlN single-layer structure, the step S117 may include forming a piezoelectric material layer on a side of the first electrode 11 away from the base substrate 10, and performing an orientation growth on the piezoelectric material layer preferably by radio frequency magnetron sputtering (or a direct current magnetron sputtering). A target material is selected as Al for the piezoelectric material of AlN. An AlN C-axis oriented piezoelectric material layer is formed by controlling an air pressure and a temperature of Ar and N₂ and a time and temperature of post-annealing in the deposition, and preferably the growth orientation is (001). The deposition process for the piezoelectric material layer may be selected from a pulsed laser sputtering (PLD) process, a molecular beam epitaxy (MBE) process, a metal organic chemical vapor deposition (MOCVD) process, a plasma enhanced chemical vapor deposition (PECVD) process, and the like. The piezoelectric layer 13 is subjected to a photolithography process including coating glue (or spraying glue), pre-baking, exposing, developing and post-baking. Then, the etching process is performed, to form a pattern of the piezoelectric layer 13. A preferred etching process may be a wet etching process or a dry etching process. Finally, a photoresist removing process is performed, so that the piezoelectric layer 13 has been formed.

S118, forming a second electrode 13 on a side of the piezoelectric layer 13 away from the first electrode 11.

In some examples, a material of the second electrode 13 may be selected from metal materials, such as Cu, Al, Mo, Co, Ag, Ti, Pt, Ru, W, Au, and alloys formed by any combination thereof. A thickness of the second electrode 13 is in a range from about 1 nm to 10 μm.

When the second electrode 13 is made of a metal material, step S118 may specifically include: depositing a third metal film on a side of the piezoelectric layer 13 away from the first electrode 11 preferably by a direct current magnetron sputtering process (or a radio frequency magnetron sputtering process) or by a pulsed laser sputtering (PLD) process, a molecular beam epitaxy (MBE) process, a thermal evaporation process, an electron beam evaporation process, or the like. Then, a photolithography process is performed on the third metal film, including coating glue (or spraying glue), pre-baking, exposing, developing and post-baking. An etching process is then performed, to form a pattern including the second electrode 13. The etching process is preferably a wet etching process, or a dry etching process. Finally, a photoresist removing process is performed, so that the second electrode 13 has been formed.

S119, forming an encapsulation layer 16 on a side of the second electrode 13 away from the base substrate 10.

In some examples, a material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

As an example, the material of the encapsulation layer 16 is the organic compound material, the step S119 may specifically include performing liquid coating of the organic material, such as spin coating, spraying, ink-jet printing, or transferring or the like, and then performing a heat curing process to form a pattern of the encapsulation layer 16.

S1110, turning over the base substrate 10 with the above structure, and forming a second heat conduction layer 18.

In some examples, the materials of the second heat conduction layer 18 and the first heat conduction layer 17 may be the same. The step S1110 may specifically include: depositing a fourth metal film on the base substrate 10 preferably by a direct current magnetron sputtering process (or a radio frequency magnetron sputtering process) or by a pulsed laser sputtering (PLD) process, a molecular beam epitaxy (MBE) process, a thermal evaporation process, an electron beam evaporation process, or the like; or by attaching a copper foil. In order to increase a thickness of the metal to facilitate the heat conduction, an electroplating thickening process may be performed. Then, a photolithography process is performed on the fourth metal film layer, including coating glue (or spraying glue), pre-baking, exposing, developing and post-baking. An etching process is then performed, to form a pattern including the second heat conduction layer, the etching process is preferably a wet etching process, or a dry etching process. Finally, a photoresist removing process is performed, so that the second heat conduction layer 18 has been formed.

It should be noted that a part of the second heat conduction layer 18 is a metal pad area bonded to the circuit board, to transfer heat generated by the device to a circuit board in time.

The embodiment of the present disclosure further provides an electronic device, which may include the bulk acoustic wave resonator of any one of the above embodiments.

It should be understood that, the above embodiments are merely exemplary embodiments adopted to explain the principles of the present disclosure, and the present disclosure is not limited thereto. It will be apparent to one of ordinary skill in the art that various changes and modifications may be made therein without departing from the spirit and scope of the present disclosure, and such changes and modifications also fall within the scope of the present disclosure.

1. A bulk acoustic wave resonator, comprising: a base substrate, a first electrode, a piezoelectric layer, and a second electrode; wherein the first electrode is on the base substrate, the second electrode is on a side of the first electrode away from the base substrate, the piezoelectric layer is between the first electrode and the second electrode; and orthographic projections of any two of the first electrode, the piezoelectric layer and the second electrode on the base substrate at least partially overlap with each other; wherein the bulk acoustic wave resonator further comprises: a first heat conduction layer on a side of the first electrode close to the base substrate.

2. The bulk acoustic wave resonator according to claim 1, wherein the base substrate comprises a first cavity extending through the base substrate in a thickness direction of the base substrate; the bulk acoustic wave resonator further comprises a second heat conduction layer; the second heat conduction layer is on a side of the base substrate away from the first electrode, the second heat conduction layer covers the first cavity, and the second heat conduction layer is in contact with the first heat conduction layer through the first cavity.

3. The bulk acoustic wave resonator according to claim 2, wherein the base substrate further comprises a plurality of heat conduction vias extending through the base substrate in the thickness direction of the base substrate; and a heat conduction electrode is in each heat conduction via, one end of the heat conduction electrode is in contact with the first heat conduction layer, and the other end of the heat conduction electrode is in contact with the second heat conduction layer.

4. The bulk acoustic wave resonator according to claim 1, further comprising an isolation layer between the first electrode and the first heat conduction layer.

5. The bulk acoustic wave resonator according to claim 1, wherein the base substrate comprises a first groove extending through a part of the base substrate in a thickness direction of the base substrate; an opening of the first groove faces to the first electrode; and an isolation layer is between the first heat conduction layer and the first electrode.

6. The bulk acoustic wave resonator according to claim 5, wherein the first thermal conduction layer comprises a first heat conduction sub-layer and a second heat conduction sub-layer; the first heat conduction sub-layer is in the first groove and covers a side wall and a bottom wall of the first groove;
the second heat conduction sub-layer is between the base substrate and the isolation layer, and the second heat conduction sub-layer and the first heat conduction sub-layer define an air gap in the first groove; and the second heat conduction sub-layer is in contact with the isolation layer.

7. The bulk acoustic wave resonator according to claim 5, wherein the base substrate comprises a plurality of heat conduction vias extending through the base substrate in the thickness direction of the base substrate; the bulk acoustic wave resonator further comprises a heat conduction electrode in each heat conduction via and a second heat conduction layer on a side of the base substrate away from the first heat conduction layer; and one end of the heat conduction electrode is in contact with the first heat conduction layer, and the other end of the heat conduction electrode is in contact with the second heat conduction layer.

8. The bulk acoustic wave resonator according to claim 1, further comprising an isolation layer between the base substrate and the first electrode; wherein a space is defined between the isolation layer and the base substrate.

9. The bulk acoustic wave resonator according to claim 8, wherein the first thermal conduction layer comprises a first heat conduction sub- layer and a second heat conduction sub-layer; the first heat conduction sub-layer is on the base substrate; the second heat conduction sub-layer is on a surface of the isolation layer close to the base substrate; and the second heat conduction sub-layer and the first heat conduction sub-layer define an air gap.

10. The bulk acoustic wave resonator according to claim 8, wherein the base substrate comprises a plurality of heat conduction vias extending through the base substrate in a thickness direction of the base substrate; the bulk acoustic wave resonator further comprises a heat conduction electrode in each heat conduction via and a second heat conduction layer on a side of the base substrate away from the first heat conduction layer; and one end of the heat conduction electrode is in contact with the first heat conduction layer, and the other end of the heat conduction electrode is in contact with the second heat conduction layer.

11. The bulk acoustic wave resonator according to claim 1, further comprising at least one mirror structure between the base substrate and the first heat conduction layer; wherein the at least one mirror structure comprises a first sub-structure layer and a second sub-structure layer which are sequentially arranged along a direction away from the base substrate, and an acoustic impedance of a material of the first sub-structure layer is greater than that of a material of the second sub-structure layer.

12. The bulk acoustic wave resonator according to claim 11, wherein the base substrate comprises a plurality of heat conduction vias extending through the base substrate in a thickness direction of the base substrate; the bulk acoustic wave resonator further comprises a heat conduction electrode in each heat conduction via and a second heat conduction layer on a side of the base substrate away from the first heat conduction layer; and one end of the heat conduction electrode is in contact with the first heat conduction layer, and the other end of the heat conduction electrode is in contact with the second heat conduction layer.

13. A method for manufacturing a bulk acoustic wave resonator, comprising: sequentially forming a first electrode, a piezoelectric layer and a second electrode on a first base substrate, wherein orthographic projections of any two of the first electrode, the piezoelectric layer and the second electrode on the first base substrate at least partially overlap with each other; wherein
the method further comprises: forming a first heat conduction layer on a side of the first electrode close to the base substrate.

14. The method for manufacturing a bulk acoustic wave resonator according to claim 13, further comprising:
performing a treatment on the base substrate, to form a first cavity extending through the base substrate in a thickness direction of the base substrate; and
forming a second heat conduction layer on a side of the base substrate away from the first electrode, wherein the second heat conduction layer covers the first cavity and is in contact with the first heat conduction layer through the first cavity; and
wherein before the first heat conduction layer is formed, the method further comprises forming a plurality of heat conduction vias extending through the base substrate in the thickness direction of the base substrate; and forming a heat conduction electrode in each heat conduction via; and
forming a second heat conduction layer on a side of the base substrate away from the first heat conduction layer; wherein one end of the heat conduction electrode is in contact with the first heat conduction layer, and the other end of the heat conduction electrode is in contact with the second heat conduction layer.

15-16. (canceled)

17. The method for manufacturing a bulk acoustic wave resonator according to claim 13, wherein before the first heat conduction layer is formed, the method further comprises performing a treatment on the base substrate, to form a first groove; wherein an opening of the first groove faces to the first electrode; and forming an isolation layer; and
wherein before the first heat conduction layer is formed, the method further comprises forming a plurality of heat conduction vias extending through the base substrate in the thickness direction of the base substrate; and forming a heat conduction electrode in each heat conduction via; and
forming a second heat conduction layer on a side of the base substrate away from the first heat conduction layer; wherein one end of the heat conduction electrode is in contact with the first heat conduction layer, and the other end of the heat conduction electrode is in contact with the second heat conduction layer.

18. The method for manufacturing a bulk acoustic wave resonator according to claim 17, wherein the first thermal conduction layer comprises a first heat conduction sub-layer and a second heat conduction sub-layer; the forming the first thermal conduction layer comprises forming the first heat conduction sub-layer in the first groove; the first heat conduction sub-layer covers a side wall and a bottom wall of the first groove; the second heat conduction sub-layer is formed between the base substrate and the isolation layer, and the second heat conduction sub-layer and the first heat conduction sub-layer define an air gap in the first groove; and the second heat conduction sub-layer is in contact with the isolation layer.

19. (canceled)

20. The method for manufacturing a bulk acoustic wave resonator according to claim 13, wherein before the first electrode is formed, the method further comprises forming an isolation layer; wherein a space is defined between the isolation layer and the base substrate;
wherein before the first heat conduction layer is formed, the method further comprises: forming a plurality of heat conduction vias extending through the base substrate in the thickness direction of the base substrate; and forming a heat conduction electrode in each heat conduction via; and
forming a second heat conduction layer on a side of the base substrate away from the first heat conduction layer; wherein one end of the heat conduction electrode is in contact with the first heat conduction layer, and the other end of the heat conduction electrode is in contact with the second heat conduction layer.

21. The method for manufacturing a bulk acoustic wave resonator according to claim 20, wherein the first thermal conduction layer comprises a first heat conduction sub-layer and a second heat conduction sub- layer; the forming the first thermal conduction layer comprises forming the first heat conduction sub-layer on the base substrate; the second heat conduction sub- layer is formed on a surface of the isolation layer close to the base substrate; and
the second heat conduction sub-layer and the first heat conduction sub-layer define an air gap.

22. (canceled)

23. The method for manufacturing a bulk acoustic wave resonator according to claim 13, further comprising: forming at least one mirror structure between the forming the first heat conduction layer and the forming the first electrode; and the forming the at least one mirror structure comprises sequentially forming a first sub-structure layer and a second sub-structure layer in a direction away from the first base substrate, and an acoustic impedance of a material of the first sub-structure layer is greater than that of a material of the second sub-structure layer;
wherein before the first heat conduction layer is formed, the method further comprises forming a plurality of heat conduction vias extending through the base substrate in the thickness direction of the base substrate; and forming a heat conduction electrode in each heat conduction via; and
forming a second heat conduction layer on a side of the base substrate away from the first heat conduction layer; wherein one end of the heat conduction electrode is in contact with the first heat conduction layer, and the other end of the heat conduction electrode is in contact with the second heat conduction layer.

24. (canceled)

25. An electronic device, comprising the bulk acoustic wave resonator according to claim 1.
